(19) United States
(12) Patent Application Publication
(10) Pub. No.: US 2015/0132587 A1
(43) Pub. Date: May 14, 2015

(54) GAS BARRIER FILM AND ELECTRONIC DEVICE USING THE SAME

(71) Applicant: Konica Minolta, Inc., Tokyo (JP)

(72) Inventor: Shoji Nishio, Tokyo (JP)

(21) Appl. No.: 14/395,922

(22) PCT Filed: Apr. 23, 2013
(86) PCT No.: PCT/JP2013/061910

§ 371 Date: Oct. 21, 2014

(30) Foreign Application Priority Data
Apr. 26, 2012 (JP) 2012-101644

(51) Int. Cl. C23C 16/56; C23C 16/455; C23C 16/30

(52) U.S. Cl. CPC C23C 16/56; C23C 16/308; C23C 16/45525
USPC 428/447

(57) ABSTRACT

Provided is a gas barrier film, which has sufficient bending property, transparency, barrier performance, and durability.

The gas barrier film includes a substrate, and a gas barrier unit being arranged on at least one side of the substrate, wherein the gas barrier unit includes a first barrier layer including an inorganic substance, a second barrier layer obtained by performing a conversion treatment to a coating film formed by coating polysilazane onto the first barrier layer, and a third barrier layer including an inorganic substance in order.

### TECHNICAL FIELD

The present invention relates to a gas barrier film having a high gas barrier property, and specifically, to a gas barrier film having a high gas barrier property, which is suitable for coating base materials of various devices or base materials. In addition, the present invention relates to an electronic device, especially, an organic electroluminescence element (hereinafter, referred to as “an organic EL element”), such as an image display element using the gas barrier film.

### BACKGROUND ART

Conventionally, a gas barrier film prepared by forming a thin film of metal oxide such as aluminum oxide, magnesium oxide, or silicon oxide on the surface of a plastic substrate or a film has been extensively used for packaging purposes to package the products that require blocking of various types of gases such as water vapor and oxygen, for example, for packaging purposes to package the foods, industrial products, and pharmaceutical products to prevent them from being deteriorated. In addition to packaging purposes, a gas barrier film is being used for a liquid crystal display element, a solar cell, an EL substrate, and the like. Especially, recently, as a result of reviewing the application of a gas barrier film to a liquid crystal display element, an organic EL element, and the like, high demands such as high long-term reliability, high flexibility of a shape, and a display practicable on a curved surface are further required as well as the demands for weight lightening or enlargement. For this reason, instead of a glass substrate which is heavy, easily broken, and is difficult to have a large area, the use of a film substrate such as a transparent plastic is started. A plastic film satisfies the above demands, and also can use a roll-to-roll way, so that as compared with glass, the productivity thereof is high, and also it is an advantage for a cost cutting.

However, a film substrate such as a transparent plastic has a problem in that a gas barrier property is deteriorated in comparison with glass. When using the substrate having a low gas barrier property, water vapor or air is permeated thereto, and thereby, for example, a liquid crystal in a liquid crystal cell is deteriorated and a display defect is generated, and thus, the display quality is deteriorated. In order to solve the above problems, it is known that a metal oxide thin film is formed on a film substrate to be a gas barrier film substrate. As a gas barrier film used for a packaging material or a liquid crystal display element, a plastic film having a deposited silicon oxide thereon (see Japanese Examined Patent Application No. 53-12953) and a plastic film having a deposited aluminum oxide thereon (see Japanese Patent Application Laid-Open No. 58-217344) are known, in which all of the above plastic films have a water vapor barrier property of about 1 g/m²·day.

However, recently, by enlarging a liquid crystal display and developing a high definition display, higher barrier performance is being demanded of a film substrate. Especially, recently, the development of an organic EL display or high vividness color liquid crystal display that requires a further higher barrier property is in progress, so that a film substrate having further higher barrier performance while maintaining the transparency that can be used therefor, especially, a film substrate having water vapor barrier performance of less than 0.1 g/m²·day is being required. In order to respond to the above demands, a film-forming method by a CVD method or a sputtering method for forming a thin film using the plasma generated by performing a glow discharge under a low-pressure condition is being reviewed as a way having an expectation for higher barrier performance. In addition, a technique for manufacturing a barrier film having an alternative lamination structure of an organic layer/inorganic layer by a vacuum evaporation method has been proposed (see Specification of U.S. Pat. No. 6,413,645 and Affinito, et al., Thin Solid Film, 290-291 (1996)).

### SUMMARY OF INVENTION

### Technical Problem

A gas barrier film also requires bending resistance or transparency as well as the water vapor barrier performance described above. However, the conventional gas barrier films are not enough from the viewpoint of the bending resistance and transparency. In addition, when an electronic device using a gas barrier film is installed under a high-temperature and high-humidity environment, there was a problem such as a deterioration of a device due to a decrease of a gas barrier performance. For this reason, an improvement of durability under a high-temperature and high-humidity environment is required.

Accordingly, an object of the present invention is to provide a gas barrier film having sufficient bending resistance, transparency, and water vapor barrier performance. In addition, another object of the present invention is to provide an electronic device having excellent durability under a high-temperature and high-humidity and capable of being weight lightening.

### Solution to Problem

The above objects are achieved by the following present invention. In other words, the present invention relates to a gas barrier film including a substrate and a gas barrier unit being arranged on at least one side of the substrate, in which the gas barrier unit includes a first barrier layer including an inorganic substance, a second barrier layer obtained by performing a conversion treatment to a coating film that is formed by coating polysilazane onto the first barrier layer, and a third barrier layer including an inorganic substance in order.

### BRIEF DESCRIPTION OF DRAWINGS

FIG. 1 is a schematic diagram illustrating an example of a vacuum plasma CVD apparatus used for forming a first layer according to the present invention.

### DESCRIPTION OF EMBODIMENTS

A gas barrier film according to the present invention includes a substrate, and a gas barrier unit that is constituted by being arranged on at least one side of the substrate, in which the gas barrier unit includes a first barrier layer including an inorganic substance, a second barrier layer obtained by performing a conversion treatment to a coating film that is formed by coating polysilazane onto the first barrier layer, and a third barrier layer including an inorganic substance in order. Hereinafter, a layer including an inorganic substance is also referred to as an inorganic substance layer, and a layer obtained by performing a conversion treatment to a coating film formed by coating polysilazane is also referred to as a polysilazane layer.

By constituting a gas barrier film as described above, a gas barrier film, which is flexible, has sufficient barrier performance, and has high transparency, can be provided. In addition, an electronic device having both of durability and a weight lightening can be provided.

It is estimated that the mechanism having the above effect is as follows. In addition, the present invention is not limited to the following mechanism.

The gas barrier film according to the present invention has a three-layer structure, that is, an inorganic substance layer/a polysilazane layer/an inorganic substance layer. For the present invention, a three-layer structure is used from the viewpoint of a bending resistance. For a layer hardness, the hardness of an inorganic substance layer is higher than that of a polysilazane layer, and thus, the three-layer structure is a structure that a soft polysilazane layer is inserted between the hard inorganic substance layers from the viewpoint of the hardness. In the state of repeating the bending of a film many times, as the hardness of an upper layer nearly corresponds with the hardness of a lower layer, the timing of the shrinkage or the extending is nearly coincident, and thus, a polysilazane conversion layer, that is, an intermediate layer, may tolerate deflection at the time of bending. Therefore, it is believed that by constituting a symmetrical layer having a polysilazane layer as the center, a bending resistance can be improved.

Here, the present invention is characteristic of using a polysilazane layer as an intermediate layer that is inserted between the inorganic substance layers.

The present inventors repeated various examinations about the causes which damage a barrier performance in the conventional gas barrier films. As a result, it was found that a micro defect of an inorganic barrier layer at the time of installing a thin film is the main factor. The decrease of the gas barrier performance caused by such a micro defect is getting serious under a high-temperature and high-humidity, thereby affecting the device performance.

The gas barrier film according to the present invention has very excellent gas barrier performance. The gas barrier film according to the present invention includes the first barrier layer on the substrate, and also the second barrier layer formed with polysilazane. It is believed that the second barrier layer blocks gas that has passed through a micro defect of the first barrier layer, and repairs the micro defect by filling the micro defect with a coating solution of polysilazane at the time of manufacturing a film, and therefore, cracks that are generated from the micro defect as the starting point at the time of bending are decreased. Therefore, since the second barrier layer is obtained by performing the conversion treatment to the coating film formed with polysilazane, gas barrier performance is improved and bending resistance is also improved as compared with the silicon oxide film or organic layer obtained by deposition, and the like. In addition, by using a polysilazane layer as a second layer, the transparency of the whole film is improved. It is believed that this is because the surface irregularity of the first barrier layer is planarized by applying a coating solution of polysilazane, and thereby the diffused reflection caused by the surface irregularity of the first barrier layer can be reduced.

In addition, it can be confirmed that the gas barrier film according to the present invention has improved durability under a high-temperature and high-humidity condition. There are some cases that under a high-temperature and high-humidity condition, external force may be applied on a gas barrier layer by a shape change (shrinkage or expansion) of the substrate due to the change of a temperature or humidity. At this time, it is believed that when the gas barrier layer has a micro defect, the cracks are further enlarged from the micro defect as the starting point by the external force, so that the gas barrier performance cannot be maintained. It is believed that the second layer obtained by converting polysilazane is present in this invention, and thus, the polysilazane repairs such a micro defect, so that the durability of a film or an electronic device using the film is improved even under a high-temperature and high-humidity condition. In addition, under a high-temperature and high-humidity condition, there are some cases that the substrate is expanded by the change of a temperature or humidity described above. In this case, since the layer constituent of the first layer of an inorganic substance has entirely different from the layer constitution of the second layer, that is, a polysilazane conversion layer, and thus, the degrees of the expansions of the layers are entirely different each other, it causes cracks in some cases. For this reason, by inserting the second layer between the first layer and third layer, both of which have the inorganic substances as a layer constitution, the upper and lower layers of the second layer exhibit the same behavior according to the expansion of the substrate under a high-temperature and high-humidity condition. For this reason, it is believed that the cracks are inhibited, and thus, the durability of the film is improved under a high-temperature and high-humidity condition.

Hereinafter, the gas barrier film and electronic device according to the present invention will be described in detail. The explanation of the constitutional elements to be described below is based on the representative embodiments of the present invention, but the present invention is not limited to such embodiments.

<Gas Barrier Film>

The preferred embodiment of the gas barrier film according to the present invention will be described.

The gas barrier film includes the gas barrier unit formed on the substrate, in which the gas barrier unit includes the first barrier layer/the second barrier layer obtained by performing a conversion treatment to a coating film formed by coating polysilazane/the third barrier layer. Preferably, the gas barrier unit consists of the first barrier layer, the second barrier layer, and the third barrier layer.

The number of the gas barrier units may be at least 1, and preferably in the range of 1 to 10 considering the transparency. In addition, since the gas barrier performance, especially, the water vapor barrier performance is improved, the film prepared by repeatedly arranging the gas barrier units is preferable. In this case, the preferred lamination number of the units is in the range of 2 to 5. In addition, in the case where the plurality of gas barrier units are present, it is preferable to share a barrier layer between the adjacent gas barrier units. In detail, in the case of two barrier units, for example, there may be a lamination type of a first barrier layer/a second barrier layer/a third barrier layer (a first barrier layer)/a second barrier layer/a third barrier layer.

<First Barrier Layer and Third Barrier Layer>

The first barrier layer and the third barrier layer include an inorganic substance. Hereinafter, the first and third barrier layers are referred to as an inorganic layer as a generic term.

The inorganic substance included in the first barrier layer and the third barrier layer is not particularly limited, but examples thereof may include metal oxide, metal nitride, metal carbide, metal oxynitride, or metal oxycarbide. Among them, from the viewpoint of the gas barrier performance, it is preferable to use oxide, nitride, carbide, oxynitride, or oxycarbide, including one or more of the metals selected from Si, Al, In, Sn, Zn, Ti, Cu, Ce, and Ta; is more preferable to use oxide, nitride, or oxynitride of the metal selected from Si, Al, In, Sn, Zn, and Ti; and is still more preferable to use oxide, nitride, or oxynitride of at least one of Si and Al. In detail, examples of the preferred inorganic substance may include silicon oxide, silicon nitride, silicon oxynitride, aluminum oxide, and aluminum silicate.

Examples of the more preferred oxynitride may include silicon oxynitride from the viewpoint of barrier performance. Here, silicon oxynitride indicates a composition composed of silicon, oxygen, and nitrogen as main constituent elements. In addition to the above main constituent elements, the constituent elements such as a small amount of hydrogen, carbon, and the like that are incorporated from a substrate atmosphere or the materials for forming a film are desirably included in the amount of less than 5%, respectively. The component ratio of silicon, oxygen, and nitrogen that constitute silicon oxynitride is preferably x/y=0.2 to 5.5 in the case where a component equation represents SiOₓN_{y}. When x/y is 5.5 or less, it is further easy to obtain sufficient gas barrier ability. In addition, when x/y is 0.2 or more, delamination between the adjacent layers is difficultly generated, and thus, it is easy to become a film that is preferably applicable for roll conveyance and the bending use. The value of x/y is more preferably 0.3 to 4.5 in view of water vapor permeability and a bending property. In addition, the values of x and y are preferably a combination to be (2x+3y)/4=0.8 to 1.1. When it is 0.8 or more, coloring is inhibited, and thus, a film is easily used as an extensive use. When it is 1.1 or less, a ratio of the constituent elements of silicon, nitrogen, and oxygen is high, and thus, a defect ratio is easily inhibited, and thereby more sufficient gas barrier ability can be expected. The combination to be (2x+3y)/4 of 0.85 to 1.1 is more preferable.

For SiOₓN_{y}, a method of controlling the values of x and y, is performed by controlling flow rates of a source gas and decomposing gas using a vacuum plasma CVD method as described below, for example. The flow rates of the source gas and decomposing gas may be properly set in view of devices, and the like to be used.

In addition, an element constitution ratio of a laminated sample may be measured by the well-known standard method by X-ray photoelectron spectroscopy (XPS) while being etched.

The content of the inorganic substance included in the first barrier layer or the third barrier layer is not particularly limited, but preferably 50 mass % or more, more preferably 80 mass % or more, still more preferably 95 mass % or more, particularly preferably 98 mass % or more, and most preferably 100 mass % (in other words, the first barrier layer and third barrier layer are constituted of inorganic substances) in the first barrier layer or the third barrier layer.

The refractive index of the inorganic layer is preferably 1.7 to 2.1 and more preferably 1.8 to 2.0. Especially, when it is 1.9 to 2.0, visible transmittance is high and high gas barrier ability is stably obtained, and thus, it is most preferable.

The smoothness of the inorganic layer formed according to the present invention is preferably less than 1 nm and more preferably 0.5 nm or less as an average roughness (an Ra value) of 1 μm square.

The film formation of the inorganic layer is preferably performed in a clean room. The degree of the cleaning is preferably class 10000 or less and more preferably class 1000 or less.

The thickness of the inorganic layer is not particularly limited, but generally in the range of 5 to 500 nm and preferably 10 to 200 nm.

The first barrier layer and third barrier layer may be a lamination structure that is constituted of a plurality of sub-layers. In this case, the respective sub-layers may have the same components or different components from each other. When the inorganic layer includes the sub-layers, the number of the sub-layers is generally about 2 to 3 layers.

In addition, the compositions of two inorganic layers (the first barrier layer and the third barrier layer) that constitute the unit of the present invention may be the same with or different from each other.

As a method for forming an inorganic layer, any kinds of methods can be used as long as the method can form a thin film to be desired. Among them, the first and third barrier layers are preferably formed by any one method of a chemical vapor deposition method, a physical vapor deposition method, and an atomic layer deposition method. According to the present invention, the second barrier layer is obtained by converting polysilazane. By forming the first and third barrier layers using the mechanism that is different from that of the second barrier layer, the film formation states of the adjacent layers may be different from each other. In this way, the gas passages in the layer for the adjacent layers become different from each other, and thus, the gas barrier performance is more improved.

In addition, the first and third barrier layers may be formed by the film-forming methods that are different from each other, but from the viewpoint of productivity, is preferably formed by the same film-forming method. In addition, the first barrier layer may be formed on the substrate and the third barrier layer may be formed on the second barrier layer.

The physical vapor deposition (PVD) method is a method for depositing a desired substance, for example, a thin film such as a carbon film on a surface of a substance in a gas phase by a physical way, and examples thereof may include a sputtering method (a DC sputtering, an RF sputtering, an ion beam sputtering, a magnetron sputtering, and the like), a vacuum vapor deposition method, an ion plating method, and the like.

The sputtering method is a method including installing a target in a vacuum chamber, smashing a rare gas element (generally, argon) ionized by applying high voltage against the target, and bouncing the atom on the surface of the target and then attaching the atom to the substrate. In this case, a reactive sputtering method may be used, in which by flowing a nitrogen gas or oxygen gas in the chamber, the element that bounces off the target by an argon gas is reacted with nitrogen and oxygen, thereby forming an inorganic layer.

Meanwhile, a chemical vapor deposition (a chemical vapor phase growth method) is a method of supplying a source gas including the components of a thin film to be desired on a substrate and depositing a film by a chemical reaction on a surface of a substrate or gas phase. In addition, in order to activate a chemical reaction, there may be a method of generating plasma, and examples thereof may include the known CVD methods such as a thermal CVD method, a catalytic chemical vapor phase growth method, a light CVD method, a vacuum plasma CVD method, and an atmospheric plasma CVD method. A plasma CVD method is preferably used from the viewpoint of a film-forming rate or treatment area, but the present invention is not particularly limited thereto. A gas barrier layer obtained by a vacuum plasma CVD method or a plasma CVD method under the pressure of atmosphere or near atmosphere is preferable because it can prepare the desired compound by selecting the conditions such as a metal compound that is a material (also referred to as a raw material), a decomposing gas, a decomposing temperature, and introducing power.

As a source gas, a source gas for forming a desired inorganic layer is properly selected, and examples thereof may include a metal compound such as a silicide, a titanium compound, a zirconium compound, an aluminum compound, a boron compound, a tin compound, and an organic metal compound.

Among them, examples of a silicide may include silane, tetramethoxy silane, tetraethoxy silane, tetra n-propoxy silane, tetraisopropoxy silane, tetra n-butoxy silane, tetra t-butoxy silane, dimethyl dimethoxy silane, dimethyl diethoxy silane, diethyl dimethoxy silane, diphenyl dimethoxy silane, methyl triethoxy silane, ethyl trimethoxy silane, phenyl triethoxy silane, (3,3,3-trifluoro propyl)trimethoxy silane, hexamethyl disiloxane, bis(dimethylamino)dimethyl silane, bis(dimethylamino)methylvinyl silane, bis(ethylamino)dimethyl silane, N,O-bis(trimethylsilyl)acetamide, bis(trimethylsilyl)carbodiimide, diethylamino trimethyl silane, dimethylamino dimethyl silane, hexamethyl disilazane, hexamethyl cyclotrisilazane, heptamethyl disilazane, nonamethyl trisilazane, octamethyl cyclotetrasilazane, tetrakisdimethylamino silane, tetraisocyanate silane, tetramethyl disilazane, tris(dimethylamino)silane, triethoxy fluorosilane, allyldimethyl silane, allyl trimethyl silane, benzyl trimethyl silane, bis(trimethylsilyl)acetylene, 1,4-bistrimethylsilyl-1,3-butadiyne, di-t-butyl silane, 1,3-disilabutane, bis(trimethylsilyl)methane, cyclopenta dienyl trimethyl silane, phenyl dimethyl silane, phenyl trimethyl silane, propargyl trimethyl silane, tetramethyl silane, trimethylsilyl acetylene, 1-(trimethylsilyl)-1-propyne, tris(trimethylsilyl)methane, tris(trimethylsilyl)silane, vinyl trimethyl silane, hexamethyl disilane, octamethyl cyclotetrasiloxane, tetramethyl cyclotetrasiloxane, hexamethyl cyclotetrasiloxane, M silicate 51, and the like.

Examples of an aluminum compound may include aluminum ethoxide, aluminum triisopropoxide, aluminum isopropoxide, aluminum n-butoxide, aluminum s-butoxide, aluminum t-butoxide, aluminum acetylacetonate, triethyl dialuminum tri-s-butoxide, and the like.

In addition, examples of a decomposing gas for obtaining an inorganic compound by decomposing a source gas including these metals may include a hydrogen gas, a methane gas, an acetylene gas, a carbon monoxide gas, a carbon dioxide gas, a nitrogen gas, an ammonia gas, a nitrous oxide gas, a nitrogen oxide gas, a nitrogen dioxide gas, an oxygen gas, and water vapor. In addition, the decomposing gas may be mixed with an inert gas such as an argon gas and a helium gas.

The desired barrier layer may be obtained by properly selecting a decomposing gas and a source gas including a source compound.

Hereinafter, a plasma CVD method that is a suitable type among the CVD methods will be described in detail.

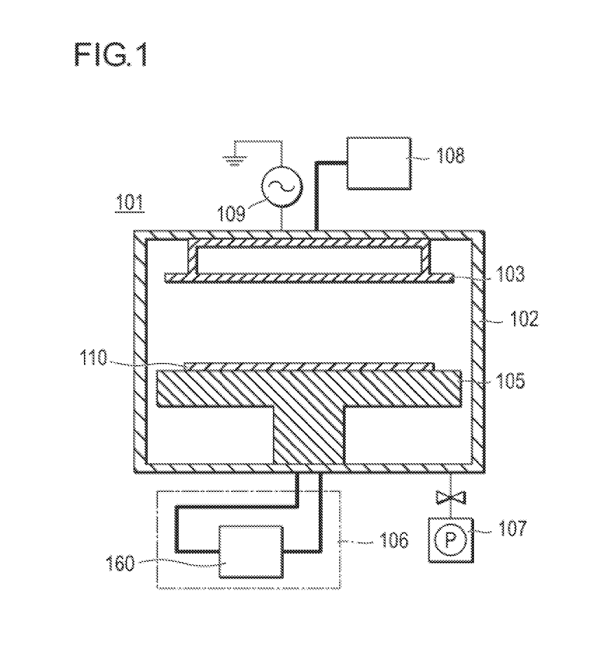

FIG. 1 is a schematic diagram illustrating an example of a vacuum plasma CVD apparatus used for forming the first layer according to the present invention.

In FIG. 1, a vacuum plasma CVD apparatus 101 includes a vacuum tank 102 and a susceptor 105 is placed on the bottom surface side of the inside of the vacuum tank 102. In addition, A cathode electrode 103 is placed at a position, facing the susceptor 105, on the ceiling side of the inside of the vacuum tank 102. A heat medium circulating system 106, a vacuum pumping system 107, a gas introduction system 108, and a high frequency power source 109 are placed outside the vacuum tank 102. A heat medium is placed in the heat medium circulating system 106. A heating cooling apparatus 160 including a pump which moves the heat medium, a heating apparatus which heats the heat medium, a cooling apparatus which cools it, a temperature sensor with which the temperature of the heat medium is measured, and a memory apparatus which memorizes a set temperature for the heat medium is disposed in the heat medium circulating system 106.

The heating cooling apparatus 160 is constituted to measure the temperature of the heat medium, to heat or cool the heat medium to the memorized set temperature, and to supply the heat medium to the susceptor 105. The supplied heat medium flows into the susceptor 105, heats or cools the susceptor 105, and returns to the heating cooling apparatus 160. The temperature of the heat medium is higher or lower than the set temperature when this occurs, and the heating cooling apparatus 160 heats or cools the heat medium to the set temperature and supplies the heat medium to the susceptor 105. A cooling medium is circulated between the susceptor and the heating cooling apparatus 160 in this manner and the susceptor 105 is heated or cooled by the supplied heat medium at the set temperature.

The vacuum tank 102 is connected to the vacuum pumping system 107, and, prior to starting film formation treatment by the vacuum plasma CVD apparatus 101, the heat medium has been heated to increase its temperature from room temperature to the set temperature while preevacuating the inside of the vacuum tank 102 and the heat medium at the set temperature has been supplied to the susceptor 105. The susceptor 105 is at room temperature when beginning to be used and the supply of the heat medium at the set temperature results in increase in the temperature of the susceptor 105.

The heat medium at the set temperature is circulated for given time and a substrate 110 to be film-formed is thereafter conveyed into the vacuum tank 102 while maintaining vacuum atmosphere in the vacuum tank 102 and is placed on the susceptor 105.

A large number of nozzles (pore) are formed in the surface, facing the susceptor 105, of the cathode electrode 103.

The cathode electrode 103 is connected to the gas introduction system 108, and a CVD gas is spouted from the nozzles of the cathode electrode 103 into the vacuum tank 102 with vacuum atmosphere by introducing the CVD gas from the gas introduction system 108 into the cathode electrode 103.

The cathode electrode 103 is connected to the high frequency power source 109 and the susceptor 105 and the vacuum tank 102 are connected to a ground potential.

Plasma of the introduced CVD gas is formed by supplying the CVD gas from the gas introduction system 108 into the vacuum tank 102, starting the high frequency power source 109 while supplying the heat medium at given temperature from the heating cooling apparatus 160 to the susceptor 105, and applying a high-frequency voltage to the cathode electrode 103. When in the plasma, the activated CVD gas reaches the surface of the substrate 110 on the susceptor 105, a first layer that is a thin film on the surface of the substrate 110 is grown.

At this time, the distance between the susceptor 105 and the cathode electrode 103 is properly set.

In addition, the flow rates of the source gas and decomposing gas are properly set in view of the kinds of the source gas and decomposing gas.

During the growth of the thin film, the thin film is formed in the state where the heat medium at the given temperature has been supplied from the heating cooling apparatus 160 to the susceptor 105 and the susceptor 105 is heated or cooled by the heat medium and maintained at given temperature. Generally, the lower limit temperature of growth temperature at which the thin film is formed depends on the film quality of the thin film while the upper limit temperature thereof depends on the permissible range of damage to the thin film that has been already formed on the substrate 110. The lower limit temperature or upper limit temperature depends on the material quality of the thin film being already formed or the material quality of the thin film to be formed, but in order to secure the film quality having high gas barrier, it is preferable that the lower limit temperature be 50° C. or higher and the upper limit temperature be the heat-resisting temperature or less of substrates.

The lower limit temperature and upper limit temperature are determined by obtaining in advance the relation between the temperature for forming the film and the film quality of the thin film, which is formed by a vacuum plasma CVD method and the relation between the temperature for forming the film and the damage affected to the object (the substrate 110) to be formed with the film. For example, the temperature of the substrate 110 during a vacuum plasma CVD process is preferably 50 to 250° C.

Furthermore, when a high-frequency voltage of 13.56 MHz or more is applied to the cathode electrode 103 to form plasma, the relationship between the temperature of the heat medium supplied to the susceptor 105 and the temperature of the substrate 110 has been premeasured and the temperature of the heat medium supplied to the susceptor 105 has been determined to maintain the temperature of the substrate 110 at the lower limit temperature or more and the upper limit temperature or less during the vacuum plasma CVD process.

For example, it is set to memorize the lower limit temperature (50° C. in this case) and to supply the heat medium, of which the temperature is controlled to the lower limit temperature or more, to the susceptor 105. The heat medium flowing back from the susceptor 105 is heated or cooled and the heat medium at the set temperature of 50° C. is supplied to the susceptor 105. For example, a mixed gas of silane gas and ammonia gas with nitrogen gas is supplied as the CVD gas to form a SiN film in the state where the temperature condition of the substrate 110 is maintained at the lower limit temperature or more and the upper limit temperature or less.

Immediately after starting the vacuum plasma CVD apparatus 101, the temperature of the susceptor 105 is room temperature and the temperature of the heating medium that is refluxed from the susceptor 105 to the heating cooling device 160 is lower than the setting temperature. Thus, immediately after the start, the heating cooling apparatus 160 heats the heat medium flowing back to increase its temperature to the set temperature and supplies the heat medium to the susceptor 105. In this case, the susceptor 105 and the substrate 110 are heated by the heat medium to increase its temperature and the substrate 110 is maintained in the range of the lower limit temperature or more and the upper limit temperature or less.

The temperature of the susceptor 105 is increased due to heat flowing in from plasma by consecutively forming thin films on a plurality of substrates 110. In this case, the heat medium flowing back from the susceptor 105 to the heating cooling apparatus 160 has higher temperature than the lower limit temperature (50° C.) and the heating cooling apparatus 160 therefore cools the heat medium and supplies the heat medium at the set temperature to the susceptor 105. As a result, the thin films can be formed while maintaining the substrates 110 in the range of the lower limit temperature or more and the upper limit temperature or less.

As described above, the heating cooling apparatus 160 heats the heat medium in the case in which the temperature of the heat medium flowing back is lower than the set temperature and cools the heat medium in the case in which the temperature thereof is higher than the set temperature, the heat medium at the set temperature is supplied to the susceptor in both cases, and the substrate 110 is therefore maintained in the temperature range of the lower limit temperature or more and the upper limit temperature or less.

After formation of the thin film with a predetermined film thickness, the substrate 110 is conveyed outside the vacuum tank 102, a substrate 110 on which no film has been formed is conveyed into the vacuum tank 102, and a thin film is formed while supplying the heat medium at the set temperature in the same manner as described above.

Generally, in the conventional organic inorganic laminated gas barrier laminate, when the inorganic layer is formed by a physical or chemical vapor deposition method, there is a problem in that the desired gas barrier property cannot be obtained. It is believed that since the sputtering method or CVD method uses high-energy particles, the pinhole or damage of the produced thin film is caused.

However, since the gas barrier film of the present invention includes a second barrier layer by applying a coating solution of polysilazane on the inorganic layer and then conducting a conversion treatment, the passage of the gas passing through a micro defect is blocked, and thus even if the inorganic layer is formed by a physical or chemical deposition method, the high barrier property can be maintained. In addition, by having the third barrier layer, even after testing the bending property, the high barrier performance can be maintained.

It is preferable that the first and third layers be constituted by forming in an atomic layer deposition method.

An atomic layer deposition method (hereinafter, also referred to as “an ALD method”) is a method of using a chemical adsorption and chemical reaction of a plurality of low-energy gases to the surface of the substrate. Since the sputtering method or CVD method uses high-energy particles, the pinhole or damage of the produced thin film is caused. However, such a method has an advantage in that since it uses a plurality of low-energy gases, the pinhole or damage rarely occurs, and a high-density single atom film may be obtained (Japanese Patent Application Laid-Open No. 2003-347042, Japanese Patent Application National Publication (Laid-Open) No. 2004-535514, and International Patent Publication No. 2004/105149 Pamphlet). For this reason, it is preferable to form at least the first barrier layer, and more preferably to form the first and third barrier layers by the ALD method since the water vapor barrier performance (WVTR) is improved.

According to the ALD method, a single atom layer (a gas molecular layer) is formed on the substrate by changing a plurality of gases as a raw material in turn and then leading the gas onto the substrate, and performing a chemical adsorption, and an inorganic layer is formed one layer by one layer by the chemical reaction on the substrate. In more detail, first, the first gas is introduced onto the substrate to form a gas molecular layer (a single atom layer). Subsequently, by introducing inert gases, the first gas is purged (removed). In addition, the produced gas molecular layer of the first gas is not purged even if the inert gas is introduced due to the chemical adsorption. Subsequently, the produced gas molecular layer is oxidized by introducing the second gas to form an inorganic film. Finally, the second gas is purged by introducing an inert gas to complete one cycle of the ALD method. By repeating the above cycle, the atomic layer is deposited one layer by one layer, and thus, the first gas barrier layer having the predetermined film thickness can be formed. In addition, according to the ALD method, an inorganic film including a shading part can be formed without depending on the surface irregularity of the substrate.

The inorganic oxides formed by the ALD method is not particularly limited, but examples thereof may include oxides of aluminum, titanium, silicon, zirconium, hafnium, and lanthanum etc. and complex oxides thereof. It is preferable that from the viewpoint where a high quality film is obtained at the temperature of 50° C. to 120° C. considering a film formation on a resin substrate, an inorganic oxide include one or more kinds selected from the group consisting of Al₂O₃, TiO₂, SiO₂ and ZrO.

In addition, by adjusting an introduction time for each gas, a film-formation temperature, and a pressure at the time of forming a film, it is possible to be intermediate oxides such as AlOₓ, TiOx, SiOx, and ZrOx, nitride, and the like, and if necessary, they can be used without any problem.

Since a surface of a substrate is required to be activated in order for a gas molecule to be adsorbed onto the substrate, it is preferable that a temperature for forming a film be a high temperature to some degree and may be properly adjusted in the range that does not exceed a glass transition temperature or a decomposition starting temperature of a plastic substrate of substrates. In the case of using a plastic substrate, the temperature in a reactor generally is about 50 to 200° C. The deposition rate for one cycle generally is 0.01 to 0.3 nm, and by repeating a cycle for forming a film, the desired thickness of the film is obtained.

For example, when the ALD layer is an aluminum oxide layer, the first gas is a gas obtained by evaporating an aluminum compound, and the second gas may be an oxidative gas. In addition, the inert gas is a gas that does not react with the first gas and/or the second gas.

The aluminum compound is not particularly limited as long as it includes aluminum and can be evaporated. Specific examples of the aluminum compound may include trimethyl aluminum (TMA), triethyl aluminum (TEA), and trichloroaluminum.

Furthermore, a source gas may be properly selected by an inorganic oxide film to be formed, and for example, the source gas disclosed in M. Ritala: Appl. Surf. Sci. 112, 223 (1997) may be used. In detail, when the inorganic oxide of the second layer is silicon oxide, the first gas is a gas obtained by evaporating a silicon compound. Examples of the silicon compound may include other chlorosilane-based compounds such as monochlorosilane (SiH₃Cl, MCS), hexachlorodisilane (Si₂Cl₆, HCD), tetrachlorosilane (SiCl₄, STC), and trichlorosilane (SiHCl₃, TCS), inorganic raw materials such as trisilane (Si₃H₈, TS), disilane (Si₂H₆, DS), and monosilane (SiH₄, MS), amino silane-based compounds such as tetrakisdimethylamino silane (Si[N(CH₃)₂]4, 4DMAS), trisdimethylamino silane (Si[N(CH₃)₂]₃H, 3DMASi), bisdiethylamino silane (Si[N(C₂H₅)₂]₂H₂, 2DEAS), and bis tertiary butylamino silane (SiH₂[NH(C₄H₉)]₂, BTBAS), and the like.

In addition, when the inorganic oxide of the second layer is titanium oxide, the first gas is a gas obtained by evaporating a titanium compound. Examples of the titanium compound may include titanium tetrachloride (TiCl₄), titanium (IV) isopropoxide (Ti[(OCH)(CH₃)₂]₄), tetrakisdimethylamino titanium ([(CH₃)₂N]₄Ti, TDMATi), tetrakisdiethylamino titanium (Ti[N(CH₂CH₃)₂]₄, TDEATi), and the like.

In addition, when the ALD layer is a zirconium oxide layer, the first gas is a gas obtained by evaporating a zirconium compound. Examples of the zirconium compound may include tetrakisdimethylamino zirconium (IV); [(CH₃)₂N]₄Zr, and the like.

The oxidative gas is not particularly limited as long as it can oxidize a gas molecular layer, and examples thereof may include ozone (O₃), water (H₂O), hydrogen peroxide (H₂O₂), methanol (CH₃OH), ethanol (C₂H₅OH), and the like. In addition, it is possible to use an oxygen radical. In the case of using a radical, it is possible to generate a high-density oxygen radical by activating a gas using the high-frequency power (for example, the power of frequency 13.56 MHz), and to further facilitate the oxidation and nitration reaction. Considering the enlargement or practicality of a device, the electric discharge in a mode of ICP (Inductively Coupled Plasma) using the powder of 13.56 MHz is preferable.

In addition, when nitride and nitrogen oxide are desired, a nitrogen radical may be used. The nitrogen radical may be produced in the same way as the way for producing an oxygen radical.

In addition, ozone and an oxygen radical are preferably used as an oxidative gas from the viewpoint of a size of a device or a reduction of one cycle time. In addition, an oxygen radical is preferably used from the viewpoint of forming a dense film at a low temperature.

As the inert gas, a rare gas (helium, neon, argon, krypton, xenon), a nitrogen gas, and the like may be used.

An introduction time of the first gas is preferably 0.05 to 10 seconds, more preferably 0.1 to 3 seconds, and still more preferably 0.5 to 2 seconds. When the introduction time of the first gas is 0.05 second or more, the time capable of forming a gas molecular layer can be sufficiently secured, and thus, it is preferable. Meanwhile, when the introduction time of the first gas is 10 seconds or less, the time required for one cycle can be reduced, and thus, it is preferable.

In addition, the introduction time of the inert gas for purging the first gas is preferably 0.05 to 10 seconds, more preferably 0.5 to 6 seconds, and still more preferably 1 to 4 seconds. When the introduction time of the inert gas is 0.05 second or more, the first gas may be sufficiently purged, and thus, it is preferable. Meanwhile, when the introduction time of the inert gas is 10 seconds or less, the time required for one cycle can be reduced and has less of an effect on the formed gas molecular layer, and thus, it is preferable.

In addition, the introduction time of the second gas is preferably 0.05 to 10 seconds, and more preferably 0.1 to 3 seconds. When the introduction time of the second gas is 0.05 second or more, the time required for oxidizing the gas molecular layer can be sufficiently secured, and thus, it is preferable. Meanwhile, the introduction time of the second gas is 10 seconds or less, the time required for one cycle can be reduced and a side reaction can be prevented, and thus, it is preferable.

In addition, the introduction time of the inert gas for purging the second gas is preferably 0.05 to 10 seconds. When the introduction time of the inert gas is 0.05 second or more, the second gas can be sufficiently purged, and thus, it is preferable. Meanwhile, when the introduction time of the inert gas is 10 seconds or less, the time required for one cycle can be reduced and has less of an effect on the formed atomic layer, and thus, it is preferable.

<Second Barrier Layer (Hereinafter, Also Referred to as a Polysilazane Layer)>

The second barrier layer is obtained by coating polysilazane onto the first barrier layer and then performing the conversion treatment to the coating film thus formed.

For forming a polysilazane layer, as a method for coating a coating solution including polysilazane (hereinafter, also referred to as a polysilazane coating solution) on the first barrier layer, a proper wet coating method that is conventionally known may be used. Specific examples thereof may include a spin coating method, a roll coating method, a flow coating method, an ink-jet method, a spray coating method, a printing method, a dip coating method, a film casting method, a bar coating method, a gravure printing method, and the like.

The coating thickness may be properly set according to a purpose. For example, as the coating thickness, the thickness after drying is preferably about 10 nm to 10 μm, and more preferably 50 nm to 1 μm. When the film thickness of the polysilazane layer is 10 nm or more, the sufficient barrier property can be obtained. Meanwhile, when it is 10 μm or less, the stable coating property at the time of forming the polysilazane layer can be obtained and also high light permeability can be realized.

(Polysilazane)

Hereinafter, polysilazane will be described.

Polysilazane is a polymer having a silicon-nitrogen bond, and a precursor inorganic polymer of a ceramic such as SiO₂ and Si₃N₄, and SiOₓN_{y} that is an intermediate solid solution of the both, having Si—N, Si—H, and N—H bonds.

The polysilazane is preferably a compound having a structure represented by the following General Formula (I).

[Chemical Formula 1]

—(SiR₁R₂—NR₃)₃— General Formula (I)

In the above General Formula (I), R₁, R₂, and R₃ are the same with or different from each other, and each independently, a hydrogen atom; or a substituted or unsubstituted alkyl group, aryl group, vinyl group, or (trialkoxysilyl)alkyl group. Here, examples of the alkyl group may include a linear chain, branched, or cyclic alkyl group having 1 to 8 carbon atoms. More specific examples thereof may include a methyl group, an ethyl group, an n-propyl group, an isopropyl group, an n-butyl group, an isobutyl group, a sec-butyl group, a tert-butyl group, an n-pentyl group, an isopentyl group, a neopentyl group, an n-hexyl group, an n-heptyl group, an n-octyl group, a 2-ethylhexyl group, a cyclopropyl group, a cyclopentyl group, a cyclohexyl group, and the like. In addition, examples of the aryl group may include an aryl group having 6 to 30 carbon atoms. More specific examples thereof may include a non-condensed hydrocarbon group such as a phenyl group, a biphenyl group, and a terphenyl group; and a condensed polycyclic hydrocarbons group such as a pentalenyl group, an indenyl group, a naphthyl group, an azulenyl group, a heptalenyl group, a biphenylenyl group, a fluorenyl group, an acenaphthylenyl group, a pleiadenyl group, an acenaphthenyl group, a phenalenyl group, a phenanthryl group, an anthryl group, a fluoranthenyl group, an acephenanthrylenyl group, an aceanthrylenyl group, a triphenylenyl group, a pyrenyl group, a chrysenyl group, and a naphthacenyl group. Examples of the (trialkoxysilyl)alkyl group may include an alkyl group having 1 to 8 carbon atoms that has a silyl group substituted with an alkoxy group having 1 to 8 carbon atoms. More specific examples thereof may include a 3-(triethoxysilyl)propyl group, a 3-(trimethoxysilyl)propyl group, and the like. In the cases of the R₁ to R₃, a substituent that is present according to circumstances is not particularly limited, but for example, an alkyl group, a halogen atom, a hydroxyl group (—OH), a mercapto group (—SH), a cyano group (—CN), a sulfo group (—SO₃H), a carboxyl group (—COOH), a nitro group (—NO₂), and the like. In addition, a substituent that is present according to circumstances may not be the same as R₁ to R₃ to be substituted. For example, when R₁ to R₃ are an alkyl group, it is not further substituted with an alkyl group. Among them, preferably, R₁, R₂, and R₃ are a hydrogen atom, a methyl group, an ethyl group, a propyl group, an isopropyl group, a butyl group, an isobutyl group, a tert-butyl group, a phenyl group, a vinyl group, a 3-(triethoxysilyl)propyl group or a 3-(trimethoxysilylpropyl) group. Preferably, R₁, R₂ and R₃ each independently are a group selected from the group consisting of a hydrogen atom, a methyl group, an ethyl group, a propyl group, an iso-propyl group, a butyl group, an iso-butyl group, a tert-butyl group, a phenyl group, a vinyl group, a 3-(triethoxysilyl)propyl group and a 3-(trimethoxysilyl)propyl group.

In addition, in the above General Formula (I), n is an integer, and n is determined such that the polysilazane having the structure represented by General Formula (I) has an number average molecular weight of 150 to 150,000 g/mole.

For the compound having the structure represented by General Formula (I), one of preferred embodiments is a perhydropolysilazane, in which all of R₁, R₂, and R₃ are hydrogen atoms from the viewpoint of a dense property of the obtained polysilazane layer. It is estimated that perhydropolysilazane has a structure having a linear chain structure and a ring structure having 6- and 8-membered ring as a center. The molecular weight thereof is about 600 to 2000 (polystyrene conversion) as a number average molecular weight (Mn), and it is a liquid or solid substance, and the state thereof depends on the molecular weight.

In addition, the polysilazane according to the present invention is preferably a compound having a structure represented by the following General Formula (II).

[Chemical Formula 2]

—[Si(R_{1′})(R_{2′})—N(R_{3′})]_{n′}—[Si(R_{4′})(R_{5′})—N(R_{6′})]_{n′} General Formula (II)

In the above General Formula (II), R_{1′}, R_{2′}, R_{3′}, R_{4′}, R_{5′}, and R_{6′}, each independently are a hydrogen atom; and a substituted or unsubstituted alkyl group, aryl group, vinyl group, or (trialkoxysilyl)alkyl group. At this time, R_{1′}, R_{2′}, R_{3′}, R_{4′}, R_{5′}, and R_{6′}, may be the same with or different from each other, respectively. The description on the substituted or unsubstituted alkyl group, aryl group, vinyl group, or (trialkoxysilyl)alkyl group is the same as the definition in General Formula (I), and thus, will not be provided. n′ and p are an integer, and determined such that the polysilazane having the structure represented by General Formula (II) has a number average molecular weight of 150 to 150,000 g/mole. In addition, n and p may be the same with or different from each other.

In General Formula (II), a compound in which R_{1′}, R_{3′}, and R_{6′}, are a hydrogen atom, respectively, R_{2′}, R_{4′}, and R_{5′}, are a methyl group, respectively; a compound in which R_{1′}, R_{3′}, and R_{6′} are a hydrogen atom, respectively, R_{2′}, and R_{4′}, are a methyl group, respectively, and R_{5′} is a vinyl group; and a compound in which R_{1′}, R_{3′}, R_{4′}, and R_{6′} are a hydrogen atom, respectively, and R_{2′} and R_{5′} are a methyl group, respectively are more preferable.

In addition, polysilazane is preferably a compound having the structure represented by the following General Formula (III).

[Chemical Formula 3]

—[Si(R_{1″})(R_{2″})—N(R_{3″})]_{n″}—[Si(R_{4″})(R_{5″})—N(R_{6″})]_{p″}—[Si(R_{7″}(R_{8″})—N(R_{9″})]_{q} General Formula (III)

In the above General Formula (III), R_{1″}, R_{2″}, R_{3″}, R_{4″}, R_{5″}, R_{6″}, R_{7″}, R_{8″}, and R_{9″} each independently are a hydrogen atom; or a substituted or unsubstituted alkyl group, aryl group, vinyl group, or (trialkoxysilyl)alkyl group. At this time, R_{1″}, R_{2″}, R_{3″}, R_{4″}, R_{5″}, R_{6″}, R_{7″}, R_{8″}, and R_{9″} may be the same with or different from each other, respectively. The description about the above substituted or unsubstituted alkyl group, aryl group, vinyl group, or (trialkoxysilyl)alkyl group is the same as the definition of the above General Formula (I), and thus, will not be provided. n″, p″ and q are an integer, respectively, and is determined such that the polysilazane having the structure represented by General Formula (III) has a number average molecular weight of 150 to 150,000 g/mole. The description about the above substituted or unsubstituted alkyl group, aryl group, vinyl group, or (trialkoxysilyl)alkyl group is the same as the definition of the above General Formula (I), and thus, will not be provided. In addition, n″, p″ and q may be the same with or different from each other.

In the above General Formula (III), a compound in which R_{1″}, R_{3″}, and R_{6″} are a hydrogen atom, respectively, R_{2″}, R_{4″}, R_{5″}, and R_{8″} are a methyl group, respectively, and R_{9″} is a (triethoxysilyl)propyl group, and R_{7″} is an alkyl group or a hydrogen atom is particularly preferable.

Meanwhile, organopolysilazane, in which a part of a hydrogen atom part bound to Si is substituted with an alkyl group, and the like, has advantages in that an adhesive property with a substrate that is a basis is improved by having an alkyl group such as a methyl group, toughness can be applied on a ceramic film by the hard and fragile polysilazane, and a generation of cracks is suppressed even in the case of having thicker (average) film thickness. The perhydropolysilazane and organopolysilazane may be properly selected according to the use thereof, or may be mixed and then used.

Other examples of the polysilazane compound may include polysilazane, which becomes a ceramic at a low temperature, such as silicon alkoxide addition polysilazane obtained by reacting the polysilazane with silicon alkoxide (Japanese Patent Application Laid-Open No. 5-238827), glycidol addition polysilazane obtained by reacting the polysilazane with glycidol (Japanese Patent Application Laid-Open No. 6-122852), alcohol addition polysilazane obtained by reacting the polysilazane with alcohol (Japanese Patent Application Laid-Open No. 6-240208), metal carbonate addition polysilazane obtained by reacting the polysilazane with metal carbonate (Japanese Patent Application Laid-Open No. 6-299118), acetyl acetonate complex addition polysilazane obtained by reacting the polysilazane with acetyl acetonate complex including metals (Japanese Patent Application Laid-Open No. 6-306329), and metal fine particles addition polysilazane obtained by adding metal fine particles (Japanese Patent Application Laid-Open No. 7-196986).

A solvent can be used in a coating solution with a formation of the polysilazane layer, and as a rate of the polysilazane in the solvent, the polysilazane is generally 1 to 80 mass %, preferably 5 to 50 mass %, and more preferably 10 to 40 mass %.

Especially, as a solvent, an organic-based solvent that does not include water and a reactive group (for example, a hydroxyl group or an amine group) and is inert to polysilazane is preferable, and a non-protonic solvent is preferable.

A solvent capable of being applied for a polysilazane coating solution according to the present invention may be a non-protonic solvent; hydrocarbon solvents, for example, aromatic hydrocarbon, aliphatic hydrocarbon such as pentane, hexane, cyclohexane, toluene, xylene, solvesso, and turpentine, and the like; halogen hydrocarbon solvents such as methylene chloride and trichloroethane; esters such as ethyl acetate and butyl acetate; ketones such as acetone and methylethyl ketone; and for example, tetrahydrofuran, dibutyl ether, mono- and polyalkylene glycol dialkylether (diglymes) ethers, or mixture of these solvents. The solvents are selected to suit the purposes such as the solubility of polysilazane or the evaporating rate of a solvent, and may be used singly or in combination of two or more kinds thereof.

Polysilazane is available in the market in a state of solution dissolved in an organic solvent, and a product on the market can be directly used as a coating solution including polysilazane. Examples of the product on the market may include AQUAMICA (Registered trademark) NN120-10, NN120-20, NAX120-20, NN110, NN310, NN320, NL110A, NL120A, NL150A, NP110, NP140, SP140, and the like, manufactured by AZ Electronic Material.

The polysilazane coating solution may include a catalyst along with polysilazane. The applicable catalyst is preferably a basic catalyst, and especially, N,N-diethyl ethanolamine, N,N-dimethyl ethanolamine, triethanolamine, triethylamine, 3-morpholino propylamine or N-heterocyclic compound is preferable. The concentration of the catalyst added is generally in the range of 0.1 to 10 mol % and preferably 0.5 to 7 mol % based on polysilazane.

For the polysilazane coating solution, the additives that are exemplified hereinafter can be used if necessary. Examples thereof may include cellulose ethers, cellulose esters; for example, natural resins such as ethyl cellulose, nitrocellulose, cellulose acetate, and cellulose acetbutyrate; for example, synthetic resins such as rubber and rosin resins; for example, polymeric resins and condensation resins; for example, aminoplast, particularly urea resins, melamine formaldehyde resins, alkyd resins, acrylic resins, polyester or denatured polyester, epoxide, polyisocyanate, or blocked polyisocyanate, polysiloxane, and the like.

The added amount of other additives is preferably 10 mass % or less and more preferably 5 wt % or less with respect to 100 mass % of the total weight of the second barrier layer.

By using the polysilazane coating solution, since there are no cracks and holes, the dense glass-like layer having excellent high barrier action to gases can be produced.

Subsequently, in the case where the coating solution includes a solvent, it is preferable to dry the solvent in the coating film formed by polysilazane before being subjected to the conversion treatment. At this time, the condition for removing water may be adopted. The drying temperature is preferably a high temperature from the viewpoint of quick treatment, but considering the heat damage to the resin film substrate, it is preferable to determine properly the temperature and treating time. For example, in the case of using a polyethylene terephthalate substrate having a glass transition temperature (Tg) of 70° C. as a plastic substrate, the heat treatment temperature may be set to be 200° C. or lower. The treating time is preferably set to be a short time in order to remove the solvent and reduce the heat damage to a substrate. When the drying temperature is 200° C. or lower, the treating time may be set to be 30 minutes or shorter.

It is preferable that for the coating film formed with polysilazane, water be removed before the conversion treatment or during the conversion treatment. For this reason, for preparing the polysilazane layer, after drying as a purpose of removing the solvent, it is preferable to include a process (dehumidification treatment) as a purpose of removing water in the coating film. By removing water before the conversion treatment or during the conversion treatment, the efficiency of subsequent conversion treatment is improved.

As a method for removing water, it is preferable to use a type of the dehumidification by maintaining the environment of low humidity. The humidity in the environment of low humidity changes according to a temperature, and thus, the preferred type of the relation between the temperature and humidity is exhibited by the determination of a dew-point temperature. The preferred dew-point temperature is 4° C. (Temperature of 25° C./Humidity of 25%) or lower, and more preferably −8° C. (Temperature of 25° C./Humidity of 10%) or lower, and it is preferable to set properly the maintained time by the film thickness of the polysilazane layer. For the condition that the film thickness of the polysilazane layer is 1.0 μm or less, it is preferable that the dew-point temperature be −8° C. or lower and the maintained time thereof be 5 minutes or longer. In addition, the lower limit of the dew-point temperature is not particularly limited, but generally −50° C. or higher, and preferably −40° C. or higher. In addition, in order to easily remove water, a reduced pressure drying process may be performed. As the pressure of the reduced pressure drying process, an atmospheric pressure to 0.1 MPa may be selected.

It is preferable that the coating film be subjected to the conversion treatment while maintaining the state thereof even after removing water.

(Conversion Treatment)

Subsequently, the coating film obtained is subjected to the conversion treatment. Here, the conversion treatment indicates a conversion reaction of polysilazane into silicon oxide and/or silicon oxynitride. In other words, it is preferable that by performing the conversion treatment, polysilazane be converted into silica to be SiOxNy. Here, x is preferably 0.5 to 2.3, more preferably 0.5 to 2.0, and still more preferably 1.2 to 2.0. In addition, y is preferably 0.1 to 3.0, more preferably 0.15 to 1.5, and still more preferably 0.2 to 1.3.

Here, by silica conversion, Si—H and N—H bond is cleaved and Si—O bond is generated to convert into ceramics such as silica. The degree of converting into ceramics may be semi-quantitatively evaluated by the following defined Equation (1) using an IR measurement.

[Mathematical Formula 1]

SiO/SiN ratio=SiO absorbance value after conversion/SiN absorbance value after conversion Equation (1)

Here, the SiO absorbance value and the SiN absorbance value are calculated by the characteristic absorptions of about 1160 cm⁻¹ and about 840 cm⁻¹, respectively. As the ratio of SiO/SiN is higher, it is exhibited that the conversion into the ceramics having the composition that is close to the silica composition is being progressed.

The ratio of SiO/SiN that is an indicator for the degree of converting into ceramics is 0.3 or more, and preferably 0.5 or more. In these range, the favorable gas barrier performance is obtained.

As a method for measuring the rate of converting into silica (x in SiOx), the rate may be measured by using an XPS method, for example.

The composition of the metal oxide (SiOx) of the second barrier layer may be measured by measuring an atomic composition ratio using an XPS surface analyzer. In addition, the composition may be also measured by measuring an atomic composition ratio, on the cutting section prepared by cutting the gas barrier layer, using an XPS surface analyzer.

A method for preparing a layer by a conversion of polysilazane into silica is not particularly limited, and examples thereof may include a heat treatment, a plasma treatment, an ozone treatment, an ultraviolet rays treatment, and the like. Since the conversion treatment may be effectively performed at a low temperature in the range that can be applied on a plastic substrate, it is preferable to perform the conversion treatment by irradiating ultraviolet rays of 400 nm or less, especially, vacuum ultraviolet rays (VUV) of the wavelength of less than 180 nm, to the coating film obtained by applying the polysilazane coating solution. The ozone or active oxygen atom generated by ultraviolet rays (synonymous with UV light) has high oxidation ability and can form a silicon oxide film or silicon oxynitride film having high dense property and insulating property at a low temperature.

By the irradiation of the ultraviolet rays, O₂ and H₂O contributing to be ceramics, an ultraviolet ray absorbent, and polysilazane itself are excited and activated. In addition, the excited polysilazane is promoted to be ceramics, and thus, the obtained ceramic film becomes dense. The irradiation of the ultraviolet rays may be effectively performed even if it is performed at any points as long as it is performed after forming a coating film.

(Ultraviolet Rays Irradiation Treatment)

As described above, for the conversion treatment, an ultraviolet rays irradiation treatment, especially, a vacuum ultraviolet rays irradiation treatment is preferably used. Here, it is preferable that at least one kind of the ultraviolet rays of 400 nm or less to be irradiated be a vacuum ultraviolet rays irradiation light (VUV) having a wavelength component of less than 180 nm. At this time, the ultraviolet rays irradiation treatment is preferably performed in the presence of air or ozone in order to effectively progress the conversion into silica.

The ultraviolet rays irradiation may be performed one time, or may be performed two or more times, repeatedly. However, at least one time of the ultraviolet rays of 400 nm or less to be irradiated is preferably an ultraviolet rays irradiation light (UV) having the wavelength component of 300 nm or less, especially, a vacuum ultraviolet rays irradiation light (VUV) having the wavelength component of less than 180 nm.

For example, when the radiation source having a radiation component of the wavelength of 300 nm or less such as a Xe₂* excimer radiator having the maximum emission of about 172 nm or a low-pressure mercury vapor lamp having an emission line of about 185 nm is used, in the presence of oxygen and/or water vapor, an ozone and oxygen radical and hydroxyl radical are very effectively generated by the photolysis caused by a high absorption coefficient of these gases in the wavelength range described above, and promotes the oxidation of the polysilazane layer. Both mechanisms, that is, the breakage of the Si—N bond and the actions of the ozone, oxygen radicals, and hydroxyl radicals can be generated only after ultraviolet rays reach on the surface of the polysilazane layer.

For this reason, in order to apply the ultraviolet rays (especially, a VUV radiation) with a dose of radioactivity as high as possible on the surface of the layer, in some cases, it is necessary for the above wavelength range that the pass length of the ultraviolet rays is reduced to correspond to the concentrations of the oxygen and water vapor to be desired by substituting with nitrogen in the passage of the ultraviolet rays (especially, a VUV radiation) treatment, and then supplying oxygen and water vapor thereto to be capable of being adjusted.

Here, in the process of irradiating the vacuum ultraviolet rays, estimated mechanism why the coating film including polysilazane is converted to be SiOₓN_{y} will be described with perhydropolysilazane as an example.

Perhydropolysilazane may be represented as the composition, “—(SiH₂—NH)ₙ—”. In the case where perhydropolysilazane is represented by SiOₓN_{y}, x=0 and y=1. In order to be x>0, an oxygen source is required from the outside. As the oxygen source, the following are used: (i) oxygen or water included in a polysilazane coating solution; (ii) oxygen or water that is taken into the coating film from the atmosphere of the coating drying process; (iii) oxygen or water, ozone, and singlet oxygen, which are taken into the coating film from the atmosphere of the vacuum ultraviolet rays irradiation process; (iv) oxygen or water that is transferred into the coating film as the out gases from the side of the substrate by the heat, and the like, applied in the vacuum ultraviolet rays irradiation process; and (v) oxygen or water that is taken into the coating film from the atmosphere when a non-oxidative atmosphere is moved into an oxidative atmosphere in the case where the vacuum ultraviolet rays irradiation process is performed in the non-oxidative atmosphere.

Meanwhile, it is considered that for y, as compared with the oxidation of Si, the condition in which the nitrification progresses is very specific, so that the upper limit thereof is basically 1.

In addition, in the relation of the combining hands of Si, O, and N, x and y are basically in the range of 2x+3y≦4. In the state of y=0 in which the oxidation has completely proceeded, a silanol group is included in the coating film and the range of 2<x<2.5 may be established in some cases.

In the vacuum ultraviolet rays irradiation process, the reaction mechanism estimated that silicon oxynitride and furthermore, silicon oxide is generated from perhydropolysilazane will be described hereinafter.

(I) Dehydrogenation and Formation of Si—N Bond Therewith

It is considered that a Si—H bond and N—H bond in perhydropolysilazane are cleaved with relative ease by the excitation due to the vacuum ultraviolet rays irradiation, and are recombined as Si—N under the inert atmosphere (a uncombined hand of Si may be formed in some cases). In other words, it is cured as a SiN_{y} composition without being oxidized. In this case, the cleavage of a polymer main chain is not generated. The cleavage of the Si—H bond or the Ni—H bond is promoted by the presence of a catalyst or by heating. Cleaved H is released as H₂ to the outside of a film.

(II) Formation of Si—O—Si Bond by Hydrolysis-Dehydration Condensation

A Si—N bond in perhydropolysilazane is hydrolyzed with water and a polymer main chain is cleaved to form Si—OH. Two Si—OH moieties are subjected to the dehydration condensation to form a Si—O—Si bond to cause curing. This is a reaction that also occurs in atmospheric air. It is considered that water vapor generated as an out gas from a substrate by the heat due to irradiation is a major water source during the irradiation with vacuum ultraviolet rays in an inert atmosphere. In the case of excessive water, Si—OH that cannot be completely subjected to dehydrative condensation remains to form a cured film having a low gas barrier property, represented by composition of SiO 2.3-2.

(III) Direct Oxidation and Formation of Si—O—Si Bond by Singlet Oxygen

When an adequate amount of oxygen exists under an atmosphere during irradiation with vacuum ultraviolet rays, singlet oxygen with very high oxidizability is formed. H and N in perhydropolysilazane are replaced by O to form a Si—O—Si bond to cause curing. It is considered that bond rearrangement may also be caused by cleaving a polymer main chain in some cases.

(IV) Oxidation with Si—N Bond Cleavage by Irradiation/Excitation with Vacuum Ultraviolet Rays

It is considered that, since the energy of vacuum ultraviolet rays is higher than the bond energy of Si—N in perhydropolysilazane, a Si—N bond is cleaved and oxidized in the presence of an oxygen source such as oxygen, ozone, or water in surroundings to form a Si—O—Si bond or Si—O—N bond to be formed. It is considered that rearrangement of a bond may also be caused by cleaving a polymer main chain in some cases.

The adjustment of the composition of silicon oxynitride of the layer, in which the layer including polysilazane is subjected to the vacuum ultraviolet irradiation, may be performed by controlling an oxidation state through properly combining the oxidation mechanism of the above (I) to (IV).

For the excellent barrier action to a gas, especially, water vapor in the vacuum ultraviolet rays irradiation process, the polysilazane layer (an amorphous polysilazane layer) applied as described above is converted into a glass-like reticulated structure of silicon dioxide. By directly starting an oxidative conversion of polysilazane frame into a three-dimensional SiO, reticulated structure by a VUV photon, the conversion is performed for a very short time in a single step.

(Vacuum Ultraviolet Rays Irradiation Treatment: Excimer Irradiation Treatment)

The most preferred conversion treatment method is treatment by vacuum ultraviolet ray irradiation (excimer irradiation treatment). The treatment by the vacuum ultraviolet ray irradiation is a method for forming a silicon oxide film at comparatively low temperature (about 200° C. or less) by making an oxidation reaction proceed by active oxygen or ozone while directly cutting an atomic bond by the action of only a photon, called a light quantum process, using the energy of light of 100 to 200 nm, higher than interatomic bonding force in a polysilazane compound, preferably using the energy of light with a wavelength of 100 to 180 nm.

At the time of performing an excimer irradiation treatment, the conversion into silica is promoted, and thus, it is preferable to perform it along with a heat treatment. As a heat treatment, for example, there may be a method for heating a coating filmby a heat conduction through contacting a substrate with a heating unit such as a heat block, a method for heating the atmosphere by the outside heater such as a resistance wire, and a method using a light in an infrared region such as an IR heater, but the present invention is not limited thereto. In addition, a method capable of maintaining the smoothness of a coating film including a silicon compound may be properly selected.

It is preferable that the heating temperature be properly adjusted in the range of 50° C. to 250° C. In addition, it is preferable that the heating time be in the range of 1 second to 10 hours.

For the irradiation with the vacuum ultraviolet rays, the irradiation strength and irradiation time are preferably set in the range, in which a substrate to be irradiated is not damaged.

In the vacuum ultraviolet rays irradiation process, the illumination of the vacuum ultraviolet rays on the coating side of the coating film of the polysilazane layer is preferably 30 to 200 mW/cm² and more preferably 50 to 160 mW/cm². In this range, the conversion efficiency is favorable and also there is minor damage affected to the substrate.

The irradiation energy amount of the vacuum ultraviolet rays on the coating side of the polysilazane layer is preferably 200 to 5000 mJ/cm², and more preferably 500 to 3000 mJ/cm². In this range, the modification efficiency is favorable and also there is minor damage affected to the substrate.

As a vacuum ultraviolet light source, a noble gas excimer lamp is preferably used. A noble gas atom such as Xe, Kr, Ar, or Ne is not chemically bound to make a molecule and is therefore referred to as an inert gas. However, an excited atom of noble gas gaining energy by discharge and/or the like can be bound to another atom to make a molecule. When the noble gas is xenon,

e+Xe→Xe*

Xe*+2Xe→Xe₂*+Xe

Xe₂*+Xe+Xe+hν(172 nm)

are established, excimer light of 172 nm is emitted when transition of Xe₂*, which is an excited excimer molecule, to a ground state occurs.

Features of the excimer lamp include high efficiency due to concentration of emission on one wavelength to cause almost no emission of light other than necessary light. Further, the temperature of an object can be kept low since surplus light is not emitted. Furthermore, instant lighting and flashing are possible since time is not needed for starting and restarting.

A method of using dielectric barrier discharge is known to provide excimer light emission. The dielectric barrier discharge is very thin discharge called micro discharge, like lightning, generated in the gas space, which is disposed between both electrodes via a dielectric such as a transparent quartz, by applying a high frequency and a high voltage of several tens of kHz to the electrodes, and, when a streamer of the micro discharge reaches a tube wall (dielectric), a dielectric surface is charged, and thus, the micro discharge becomes extinct.

It is discharge in which the micro discharge spreads over the whole tube wall and generation and extinction thereof are repeated. Therefore, light flicker which can be recognized even by naked eyes occurs. Since a streamer at very high temperature reaches directly the tube wall locally, there is also a possibility in that deterioration in the tube wall may be accelerated.

For a method of efficiently obtaining excimer light emission, electrodeless electric field discharge, other than the dielectric barrier discharge, is also possible. It is electrodeless electric field discharge by capacitive coupling and is also sometimes called RF discharge. Although a lamp, electrodes, and arrangement thereof may be basically the same as those in the dielectric barrier discharge, a high frequency applied between both electrodes illuminates at several of MHz. In the electrodeless electric field discharge, discharge uniform in terms of space and time is obtained as described above and a long-lasting lamp without flicker is therefore obtained.

In the case of the dielectric barrier discharge, since micro discharge occurs only between the electrodes, the outside electrode must cover the whole external surface and have a material, through which light passes, for taking out light to the outside, in order to effect discharge in the whole discharge space.

Therefore, the electrode in which thin metal wires are reticulated is used. This electrode is easily damaged by ozone, and the like, generated by vacuum-ultraviolet light in the oxygen atmosphere since wires which are as thin as possible are used so as not to block light. For preventing this, it is necessary to make the periphery of the lamp, that is, the inside of an irradiation apparatus have inert gas atmosphere such as nitrogen and to dispose a window with synthetic quartz to take out irradiated light. The window with synthetic quartz is not only an expensive expendable product but also causes the loss of light.

Since a double cylinder type lamp has an outer diameter of about 25 mm, a difference between the distances to an irradiated surface just under a lamp axis and on the side surface of the lamp is unnegligible to cause a significant difference in illuminance. Accordingly, even if such lamps are closely arranged, no uniform illumination distribution is obtained. The irradiation apparatus provided with the window with synthetic quartz enables equal distances in the oxygen atmosphere and provides a uniform illumination distribution.

It is not necessary to reticulate an external electrode when electrodeless electric field discharge is used. Only by disposing the external electrode on a part of the external surface of the lamp, glow discharge spreads over the whole discharge space. For the external electrode, an electrode which serves as a light reflecting plate typically made of an aluminum block is used on the back surface of the lamp. However, since the outer diameter of the lamp is large as in the case of the dielectric barrier discharge, synthetic quartz is required for making a uniform illumination distribution.

The maximum feature of a narrow tube excimer lamp is a simple structure. Both ends of a quartz tube are only closed to seal a gas for excimer light emission therein.

The tube of the narrow tube lamp has an outer diameter of about 6 nm to 12 mm, and a high voltage is needed for starting when it is too thick.

As discharge form, any of dielectric barrier discharge and electrodeless electric field discharge can be used. As for the shape of the electrode, a surface contacting with the lamp may be planar; however, the lamp can be well fixed and the electrode closely contacts with the lamp to stabilize discharge well by the shape fitting with the curved surface of the lamp. Further, a light reflecting plate can be also made when the curved surface is made to be a specular surface with aluminum.

The preferred radiation source is an excimer radiator (for example, a Xe excimer lamp) having a maximum radiation of about 172 nm, a low-pressure mercury water vapor lamp having the emission line of about 185 nm, an intermediate-pressure and high-pressure mercury water vapor lamp having a wavelength component of 230 nm or less, and an excimer lamp having a maximum radiation of about 222 nm.

Among them, the Xe excimer lamp is excellent in luminous efficiency since an ultraviolet ray with a short wavelength of 172 nm is radiated as a single wavelength. This light enables a high concentration of a radical oxygen atomic species or ozone to be generated with a very small amount of oxygen because of having a high oxygen absorption coefficient. Further, the energy of light with a short wavelength of 172 nm is known to have a high capacity of dissociating the bond of organic matter. The conversion of a polysilazane layer can be realized in a short time by the high energy of this active oxygen or ozone and ultraviolet radiation.

The excimer lamp can be made to illuminate by input of a low power because of having high light generation efficiency. Further, it does not emit light with a long wavelength which becomes a factor for increasing temperature due to light, but irradiates energy in an ultraviolet range, that is, with a short wavelength, and thus, has the characteristic capable of suppressing increase in the surface temperature of an article to be irradiated. Therefore, it is suitable for a flexible film material such as PET, which is considered to be easily subject to heat effect.

Accordingly, shortening of process time and reduction in the area of a facility, caused by a high throughput, and irradiation of an organic material, a plastic substrate, or the like, which is easily damaged by heat, are made to be possible in comparison with the low-pressure mercury lamp which emits wavelengths of 185 nm and 254 nm and the plasma cleaning.

In addition, the action of UV light without including a wavelength component of 180 nm or less from the low-pressure mercury lamp (a HgLP lamp) (185 nm and 254 nm) which emits the wavelengths of 185 nm and 254 nm or a KrCl*excimer lamp (222 nm) is limited to a direct photolysis action to a Si—N bond, and in other words, an oxygen radical or hydroxyl radical is not generated. In this case, since the degree of absorption is as small as negligible, the limit relating to the concentrations of oxygen and water vapor is not required. Another advantage of the light having shorter wavelength is that the penetration depth to the polysilazane layer is bigger.

A reaction during irradiation with ultraviolet rays requires oxygen. Since vacuum ultraviolet rays are easily prone to decrease efficiency in an ultraviolet ray irradiation process due to absorption by oxygen, it is preferable to perform the irradiation with vacuum ultraviolet rays in the state in which an oxygen concentration and a water vapor concentration is as low as possible. The oxygen concentration during the irradiation with vacuum ultraviolet rays is preferably 10 to 210,000 volume ppm, more preferably 50 to 10,000 volume ppm, and still more preferably 500 to 5,000 volume ppm. In addition, the water vapor concentration between the conversion processes is preferably in the range of 1,000 to 4,000 volume ppm.

As a gas filled in an irradiation atmosphere used during the irradiation with vacuum ultraviolet rays, a dry inert gas is preferred, and a dry nitrogen gas is particularly preferred from the viewpoint of a cost. The adjustment of the oxygen concentration can be performed by measuring the flow rates of an oxygen gas and an inert gas introduced into an irradiation house and changing a flow ratio.

<Substrate>

The materials constituting a substrate is not particularly limited, but a synthetic resin (plastic) is preferable from the viewpoint of weight lightening. The material quality and thickness of the plastic substrate used are not particularly limited as long as the film is capable of maintaining a barrier laminate, and the plastic substrate may be properly selected according to the use purpose, and the like. Specific examples of the plastic substrate may include thermoplastic resins such as polyester resins such as polyethylene terephthalate, polybutylene naphthalate, (PEN) polyethylene terephthalate, and polyethylene naphthalate (PEN), methacrylic resin, a methacrylate-maleic acid copolymer, a polystyrene resin, a transparent fluoric resin, polyimide, a fluorination polyimide resin, a polyamide resin, a polyamideimide resin, a polyetherimide resin, a cellulose acylate resin, a polyurethane resin, a polyetheretherketone resin, a polycarbonate resin, an alicyclic polyolefin resin, a polyacrylate resin, a polyether sulfone resin, a polysulfone resin, a cycloolefin copolymer, a fluorene ring-modified polycarbonate resin, an alicyclic-modified polycarbonate resin, a fluorene ring-modified polyester resin, and a acryloyl compound.

When the gas barrier film of the present invention is used as a substrate of a device such as an organic EL element to be described below, the plastic substrate is preferably composed of a material having heat resistance. In detail, it is preferably constituted of a transparent material having a glass transition temperature (Tg) of 100° C. or higher and/or linear thermal expansion coefficient of 40 ppm/° C. or lower, and having high heat resistance. The Tg and linear thermal expansion coefficient can be adjusted by additives, and the like. Examples of the thermoplastic resin may include polyethylene naphthalate (PEN: 120° C.), polycarbonate (PC: 140° C.), alicyclicpolyolefin (for example, ZEONOR 1600 prepared by Zeon Corporation.: 160° C.), polyacrylate (PAr: 210° C.), polyether sulfone (PES: 220° C.), polysulfone (PSF: 190° C.), a cycloolefin copolymer (COC: the compound disclosed in Japanese Patent Application Laid-Open No. 2001-150584: 162° C.), polyimide (for example, Neo Prim prepared by Mitsubishi Gas Chemical Company, Inc.: 260° C.), fluorene ring-modified polycarbonate (BCF-PC: the compound disclosed in Japanese Patent Application Laid-Open No. 2000-227603: 225° C.), alicyclic-modified polycarbonate (IP-PC: the compound disclosed in Japanese Patent Application Laid-Open No. 2000-227603: 205° C.), and an acryloyl compound (the compound disclosed in Japanese Patent Application Laid-Open No. 2002-80616: 300° C. or higher) (the parenthesis represents Tg). Especially, in the case of requiring transparency, the alicyclic polyolefin and the like may be preferably used.

In the case where the gas barrier film is used in combination with a polarizing plate, it is preferable that the gas barrier unit (laminate) of the gas barrier film be faced at the inside of a cell and be disposed in the innermost (adjacent to the element). At that time, since the gas barrier film is disposed in the inside of the cell relative to the polarizing plate, a retardation value of the gas barrier film is important. As to a use form of the gas barrier film in such an embodiment, it is preferable that a gas barrier film using a base material film having a retardation value of 10 nm or less and a circular polarizing plate (quarter-wave plate+(half-wave plate)+linear polarizing plate) be laminated and used, or that a linear polarizing plate be combined and used with a gas barrier film using a base material film having a retardation value of from 100 nm to 180 nm, which can be used as a quarter-wave plate.

Examples of the base material film having a retardation of 10 nm or less may include cellulose triacetate (FUJITAC, manufactured by Fujifilm Corporation), polycarbonates (PURE-ACE, manufactured by Teijin Limited; and ELMECH, manufactured by Kaneka Corporation), cycloolefin polymers (ARTON, manufactured by JSR Corporation; and ZEONOR, manufactured by Zeon Corporation), cycloolefin copolymers (APEL (pellet), manufactured by Mitsui Chemicals, Inc.; and TOPAS (pellet), manufactured by Polyplastics Co., Ltd.), polyarylates (U100 (pellet), manufactured by Unitika Ltd.) and transparent polyimides (NEOPULIM, manufactured by Mitsubishi Gas Chemical Company, Inc.).

In addition, films obtained by properly stretching the foregoing film to adjust it so as to have a desired retardation value can be used as the quarter-wave plate.

The substrate is preferably transparent. This is because when the substrate is transparent and the layer formed on the substrate is also transparent, it is possible to be a transparent gas barrier film, and thus, it is also possible to be a transparent substrate of an organic EL element. In detail, the light transmittance of the substrate is generally 80% or more, preferably 85% or more, and more preferably 90% or more. The light transmittance can be measured by a method described in JIS-K7105 (2010), namely by measuring a total light transmittance and an amount of scattered light using an integrating sphere type light transmittance analyzer and subtracting the diffuse transmittance from the total light transmittance.

Even in the case where the gas barrier film is used for display use, for example, when it is not disposed on the side of an observer, the transparency is not always required. Accordingly, in such a case, an opaque material can also be used as the plastic substrate. Examples of the opaque material may include known liquid crystal polymers such as polyimides and polyacrylonitrile.

The thickness of the substrate is properly selected depending upon the use, and thus, is not particularly limited, however, it is typically from 1 to 800 μm, and preferably from 10 to 200 μm.

<Other Treatments•Other Layers>

The various known treatments (for example, a corona discharge treatment, a flame treatment, an oxidation treatment, a plasma treatment, an UV treatment, and a glow discharge treatment) may be performed to improve an adhesive property on both sides of the substrate, at least the side provided with the barrier layer, and also, if necessary, another organic layer (for example, an anchor coat layer, a primer layer, a bleedout layer), and functional layers such as a protective layer, an absorption layer, and an antistatic layer may be provided. Here, the anchor coat layer, primer layer, and bleedout preventing layer will be described.

(Anchor Coat Layer)

An anchor coat layer may be formed on the surface of the substrate as an easy adhesive layer for the purpose of improving an adhesive property (a adhesion property) with the barrier layer. Examples of anchor coat agents used for the anchor coat layer may include polyester resins, isocyanate resins, urethane resins, acrylic resins, ethylene vinyl alcohol resins, vinyl modified resins, epoxy resins, modified styrene resins, modified silicone resins, alkyl titanate, and the like, which can be used singly or in combination of two or more kinds thereof. As the anchor coat agents, products on the market may be used. In detail, a siloxane-based UV-cured polymer solution (3% isopropyl alcohol solution of “X-12-2400” manufactured by Shin-Etsu Chemical Co., Ltd.) can be used.

In addition, especially in the case where an anchor coat layer is formed as the lower layer at the time of forming a first or third barrier layer by an ALD method, examples of the anchor coat agent may include water-soluble polymers such as gelatine (derivative), casein, agar, an alignate, starch, polyvinyl alcohol, a polyacrylic acid (salt), polymaleic acid (salt), cellulose derivatives such as carboxymethylcellulose, and hydroxyethyl cellulose; polyvinyl alcohol, and the like.

An additive known in the art can also be added to these anchor coat agents. In addition, a substrate may be coated with the anchor coat agent by the known methods such as a roll coating, a gravure coating, a knife coating, a dip coating, and a spray coating, and be dried to remove a solvent, a diluent, and the like. The applying amount of the coated anchor coat agent as described above is preferably about 0.1 to 5 g/m² (in a dry state). In addition, the substrate attached with an easy adhesive layer that is available on the market may be used.

The thickness of the anchor coat layer is not particularly limited, but preferably about 0.5 to 10.0 μm.

In addition, the anchor coat layer may be used as the following smooth layer.

(Primer Layer (Smooth Layer))

The gas barrier film may also include a primer layer (a smooth layer). The primer layer is disposed in order to flatten the roughened surface of a transparent resin film substrate, on which projections, and the like are present, or to fill and flatten recesses and projections or pinholes generated in the transparent first barrier layer by the projections present on the transparent resin film substrate. Such a primer layer is basically formed by curing a photosensitive material or a thermosetting material.

Examples of the photosensitive material used for forming the primer layer may include a resin composition comprising an acrylate compound having a radical reactive unsaturated compound; a resin composition comprising an acrylate compound and a mercapto compound having a thiol group; a resin composition in which a polyfunctional acrylate monomer such as epoxy acrylate, urethane acrylate, polyester acrylate, polyether acrylate, polyethylene glycol acrylate, or glycerol methacrylate is dissolved; and the like. In detail, an UV-cured organic/inorganic hybrid hard coat material OPSTAR (Registered trademark) series manufactured by JSR Corporation can be used. In addition, such resin compositions as described above can also be optionally mixed and used, and the photosensitive material is not particularly limited as long as the material is a photosensitive resin containing a reactive monomer having one or more photopolymerizable unsaturated bonds in a molecule. In addition, such resin compositions as described above may also be optionally mixed and used, and the photosensitive material is not particularly limited as long as the material is a photosensitive resin containing a reactive monomer having one or more photopolymerizable unsaturated bonds in a molecule.

Examples of the reactive monomer having one or more photopolymerizable unsaturated bonds in a molecule may include methyl acrylate, ethyl acrylate, n-propyl acrylate, isopropyl acrylate, n-butyl acrylate, isobutyl acrylate, tert-butyl acrylate, n-pentyl acrylate, n-hexyl acrylate, 2-ethyl hexyl acrylate, n-octylacrylate, n-decylacrylate, hydroxyethyl acrylate, hydroxypropyl acrylate, allyl acrylate, benzyl acrylate, butoxyethyl acrylate, butoxyethylene glycol acrylate, cyclohexyl acrylate, dicyclopentanyl acrylate, 2-ethyl hexyl acrylate, glycerol acrylate, glycidyl acrylate, 2-hydroxyethyl acrylate, 2-hydroxypropyl acrylate, isobornyl acrylate, isodexyl acrylate, isooctyl acrylate, lauryl acrylate, 2-methoxyethyl acrylate, methoxy ethylene glycol acrylate, phenoxy ethyl acrylate, stearyl acrylate, ethylene glycol diacrylate, diethylene glycol diacrylate, 1,4-butanediol diacrylate, 1,5-pentanediol diacrylate, 1,6-hexadiol diacrylate, 1,3-propanediol acrylate, 1,4-cyclohexanediol diacrylate, 2,2-dimethylolpropane diacrylate, glycerol diacrylate, tripropylene glycol diacrylate, glycerol triacrylate, trimethylolpropane triacrylate, polyoxyethyl trimethylolpropane triacrylate, pentaerythritol triacrylate, pentaerythritoltetraacrylate, ethylene oxide modified pentaerythritol triacrylate, ethylene oxide modified pentaerythritol tetraacrylate, propione oxide modified pentaerythritol triacrylate, propione oxide modified pentaerythritoltetraacrylate, triethylene glycol diacrylate, polyoxypropyl trimethylolpropane triacrylate, butylene glycol diacrylate, 1,2,4-butanediol triacrylate, 2,2,4-trimethyl-1,3-pentadiol diacrylate, diallyl fumarate, 1,10-decanediol dimethylacrylate, pentaerythritol hexaacrylate, and monomers obtained by substituting the above-described acrylates by methacrylates, γ-methacryloxypropyltrimethoxysilane, 1-vinyl-2-pyrrolidone, and the like. The above-described reactive monomers may be used singly or as mixtures of two or more kinds thereof or as mixtures with other compounds.

A composition of the photosensitive resin includes a photopolymerization initiator.

Examples of the photopolymerization initiator may include benzophenone, o-benzoylmethyl benzoate, 4,4-bis(dimethylamine)benzophenone, 4,4-bis(diethylamine)benzophenone, α-amino.acetophenone, 4,4-dichlorobenzophenone, 4-benzoyl-4-methyldiphenyl ketone, dibenzyl ketone, fluorenone, 2,2 diethoxyacetophenone, 2,2-dimethoxy-2-phenylacetophenone, 2-hydroxy-2-methylpropiophenone, p-tert-butyldichloroacetophenone, thioxanthone, 2-methylthioxanthone, 2-chlorothioxanthone, 2-isopropylthioxanthone, diethylthioxanthone, benzyldimethyl ketal, benzyl methoxyethyl acetal, benzoin methyl ether, benzoin butyl ether, anthraquinone, 2-tert-butylanthraquinone, 2-amylanthraquinone, β-chloroanthraquinone, anthrone, benzanthrone, dibenzosuberone, methyleneanthrone, 4-azidobenzylacetophenone, 2,6-bis(p-azidobenzylidene)cyclohexane, 2,6-bis(p-azidobenzylidene)-4-methylcyclohexanone, 2-phenyl-1,2-butadione-2-(o-methoxycarbonyl)oxime, 1-phenyl-propanedione-2-(o-ethoxycarbonyl)oxime, 1,3-diphenyl-propanetrione-2-(o-ethoxycarbonyl)oxime, 1-phenyl-3-ethoxy-propanetrione-2-(o-benzoyl)oxime, Michler's ketone, 2-methyl[4-(methylthio)phenyl]-2-morpholino-1-propane, 2-benzyl-2-dimethylamino-1-(4-morpholinophenyl)-butanone-1, naphthalenesulfonyl chloride, quinoline sulfonyl chloride, n-phenylthioacridone, 4,4-azobisisobutyronitrile, diphenyl disulfide, benzthiazole disulfide, triphenylphosphine, camphorquinone, carbon tetrabromide, tribromophenylsulfone, benzoin peroxide, and eosine, as well as combinations of a photoreductive pigment such as Methylene Blue and a reducing agent such as ascorbic acid or triethanolamine, and the like. These photopolymerization initiators may be used singly or in combination of two or more kinds thereof.

Specific examples of the thermosetting material may include tutoProm series (organic polysilazane) manufactured by Clariant, SP COAT heat-resistant clear coating material manufactured by Ceramic Coat Co., Ltd., nanohybrid silicone manufactured by ADEKA Corporation, UNIDIC (Registered trademark) V-8000 Series and EPICLON (Registered trademark) EXA-4710 (super-high-heat-resistant epoxy resin), manufactured by DIC Corporation, various silicone resins X-12-2400 (Product name) manufactured by Shin-Etsu Chemical Co., Ltd., inorganic•organic nanocomposite material SSG coat manufactured by Nitto Boseki Co., Ltd., thermosetting urethane resins comprising acrylic polyols and isocyanate prepolymers, phenol resins, urea melamine resins, epoxy resins, unsaturated polyester resins, silicone resins, and the like. Among them, epoxy resin-based materials having heat resistance are particularly preferred.

The method for forming a primer layer is not particularly limited, but the formation is preferably performed by wet coating methods such as spin coating methods, spray methods, blade coating methods, and dip methods, and dry coating methods such as vapor deposition methods.

In the formation of the primer layer, an additive such as an oxidation inhibitor, an ultraviolet ray absorbing agent, or a plasticizer may be added to the above-mentioned photosensitive resin, if necessary. A resin or an additive suitable for improving the film forming property or for preventing occurrence of pinholes on the film may also be used in any primer layer irrespective of the lamination position of the primer layer.

The solvent used for forming a primer layer using a coating solution prepared by dissolving or dispersing a photosensitive resin in a solvent may be alcohols such as methanol, ethanol, n-propanol, isopropanol, ethylene glycol, and propylene glycol, terpenes such as α- or β-terpineol, ketones such as acetone, methyl ethyl ketone, cyclohexanone, N-methyl-2-pyrrolidone, diethyl ketone, 2-heptanone, and 4-heptanone, aromatic hydrocarbons such as toluene, xylene, and tetramethyl benzene, glycol ethers such as cellosolve, methylcellosolve, ethylcellosolve, carbitol, methyl carbitol, ethyl carbitol, butyl carbitol, propylene glycol monomethyl ether, propylene glycol monoethyl ether, dipropylene glycol monomethyl ether, dipropylene glycol monoethyl ether, triethylene glycol monomethyl ether, and triethylene glycol monoethyl ethers, ester acetates such as ethyl acetate, butyl acetate, cellosolve acetate, ethyl cellosolve acetate, butyl cellosolve acetate, carbitol acetate, ethyl carbitol acetate, butyl carbitol acetate, propylene glycol monomethyl ether acetate, propylene glycol monoethyl ether acetate, 2-methoxyethyl acetate, cyclohexyl acetate, 2-ethoxyethyl acetate, and 3-methoxybutyl acetate, diethylene glycol dialkyl ether, dipropylene glycol dialkyl ether, 3-ethoxy ethyl propionate, methyl benzoate, N,N-dimethyl acetamide, N,N-dimethylformamide, and the like.

The smoothness of the primer layer is a value represented by the surface roughness specified in JIS B 0601:2001, and a maximum cross-sectional height Rt(p) is preferably 10 nm or more and 30 nm or less.

The surface roughness is calculated by the section curve of the irregularity that is continuously measured with a detector having the stylus probe of micro tip radius consecutively in AFM (atomic force microscope). By the stylus probe of micro tip radius, many measurements are performed in the sections of the tens of μm as a measuring direction to obtain the roughness relating to the fine amplitude of the irregularity.

The thickness of the primer layer is not particularly limited, but preferably in the range of 0.5 to 10 μm.

(Bleedout Preventing Layer)

The gas barrier film may also have a bleedout preventing layer. The bleedout preventing layer is disposed on the surface opposite to the surface of the substrate having the smooth layer for the purpose of inhibiting the phenomenon of the contamination of the contact surface due to the migration of an unreacted oligomer, and the like, from the substrate of the film to the surface, when the film having the smooth layer is heated. As long as the bleedout preventing layer has this function, the bleedout preventing layer may basically have the same constitution as that of the smooth layer.

As an unsaturated organic compound having a polymerizable unsaturated group, which can be incorporated in the bleedout preventing layer, examples thereof may include a polyvalent unsaturated organic compound having two or more polymerizable unsaturated groups in the molecule or a monovalent unsaturated organic compound having one polymerizable unsaturated group in the molecule.

Here, examples of the polyvalent unsaturated organic compound may include ethylene glycol di(meth)acrylate, diethylene glycol di(meth)acrylate, glycerol di(meth)acrylate, glycerol tri(meth)acrylate, 1,4-butanediol di(meth)acrylate, 1,6-hexanediol di(meth)acrylate, neopentylglycol di(meth)acrylate, trimethylol propane tri(meth)acrylate, dicyclopentanyl di(meth)acrylate, pentaerythritol tri(meth)acrylate, pentaerythritol tetra(meth)acrylate, dipentaerythritol hexa(meth)acrylate, dipentaerythritol monohydroxy penta(meth)acrylate, ditrimethylol propane tetra(meth)acrylate, diethylene glycol di(meth)acrylate, polyethylene glycol di(meth)acrylate, tripropylene glycol di(meth)acrylate, polypropylene glycol di(meth)acrylate, and the like.

In addition, examples of the monovalent unsaturated organic compound may include methyl (meth)acrylate, ethyl (meth)acrylate, propyl(meth)acrylate, butyl (meth)acrylate, 2-ethylhexyl(meth)acrylate, isodecyl(meth)acrylate, lauryl(meth)acrylate, stearyl(meth)acrylate, allyl(meth)acrylate, cyclohexyl(meth)acrylate, methyl cyclohexyl(meth)acrylate, isobornyl(meth)acrylate, 2-hydroxyethyl (meth)acrylate, 2-hydroxypropyl(meth)acrylate, glycerol(meth)acrylate, glycidyl(meth)acrylate, benzyl (meth)acrylate, 2-ethoxyethyl (meth)acrylate, 2-(2-ethoxyethoxy)ethyl (meth)acrylate, butoxyethyl (meth)acrylate, 2-methoxyethyl (meth)acrylate, methoxydiethylene glycol(meth)acrylate, methoxy triethylene glycol(meth)acrylate, methoxypolyethylene glycol(meth)acrylate, 2-methoxypropyl(meth)acrylate, methoxy dipropylene glycol(meth)acrylate, methoxy tripropylene glycol(meth)acrylate, methoxypolypropylene glycol(meth)acrylate, polyethylene glycol(meth)acrylate, polypropylene glycol(meth)acrylate, and the like.

As other additive agents, a matting agent may be included. As a matting agent, the inorganic particles having an average particle diameter of about 0.1 to 5 μm are preferred.

As such inorganic particles, one kind or two or more kinds in combination of silica, alumina, talc, clay, calcium carbonate, magnesium carbonate, barium sulfate, aluminum hydroxide, titanium dioxide, zirconium oxide, and the like may be used.

Here, the matting agent that is composed of the inorganic particles is desirably mixed in the ratio of 2 parts by weight or more, preferably 4 parts by weight or more, and more preferably 6 parts by weight or more, but 20 parts by weight or less, preferably 18 parts by weight or less, and more preferably 16 parts by weight or less, with respect to 100 parts by weight of the solid content of a hard coat agent.

In addition, in the bleedout preventing layer, a thermoplastic resin, a thermosetting resin, an ionizing radiation curable resin, a photopolymerizable initiator, or the like, as another component except the hard coat agent and the matting agent, may also be included.

As the above-described thermoplastic resin, there may be cellulose derivatives such as acetylcellulose, nitrocellulose, acetyl butyl cellulose, ethyl cellulose, and methylcellulose, vinyl-based resins such as vinyl acetate and a copolymer thereof, vinyl chloride and a copolymer thereof, and vinylidene chloride and a copolymer thereof, acetal-based resins such as polyvinyl formal, and polyvinyl butyral, acrylic-based resins such as acrylic resin and a copolymer thereof, and a methacrylic resin and a copolymer thereof, polystyrene resins, polyamide resins, linear polyester resins, polycarbonate resins, and the like.

In addition, examples of the thermosetting resin may include a thermosetting urethane resin that is composed of acrylic polyol and isocyanate prepolymers, a phenolic resin, an urea melamine resin, an epoxy resin, an unsaturated polyester resin, a silicone resin, and the like.

In addition, as the ionizing radiation curable resin, the resin cured by irradiating the ionizing radiation (ultraviolet rays or electron beam) to the ionizing radiation curable coating materials prepared by mixing one kind or two or more kinds of the photopolymerizable prepolymers or photopolymerizable monomers may be used. Here, as the photopolymerizable prepolymer, it is preferable that the acrylic-based prepolymer having a three-dimensional mesh structure generated by having two or more of the acryloyl groups in one molecule and cross-linking be especially used. As the acrylic-based prepolymer, urethane acrylate, polyester acrylate, epoxy acrylate, melamine arylate, and the like may be used. In addition, as the photopolymerizable monomer, the above-described polyvalent unsaturated organic compounds, and the like may be used.

In addition, examples of the photopolymerizable initiator may include acetophenone, benzophenone, Michler's ketone, benzoin, benzyl methyl ketal, benzoin benzoate, hydroxy cyclohexyl phenyl ketone, 2-methyl-1-(4-(methylthio)phenyl)-2-(4-morpholinyl)-1-propane, α-acyl oxime ester, thioxanthones, and the like.

The bleedout preventing layer as described above can be formed by preparing a coating solution by blending a hard coat agent, a matting agent, and if necessary another component with an diluting solvent which is appropriately optionally used, coating the coating solution on the surface of the substrate film by a coating method known in the art, and then, irradiating the solution with ionizing radiation to cure the solution. In addition, a method for irradiation with ionizing radiation can be performed by irradiation with ultraviolet rays in a wavelength region of 100 to 400 nm, preferably 200 to 400 nm, emitted from an ultra-high-pressure mercury lamp, a high pressure mercury lamp, a low-pressure mercury lamp, a carbon arc, a metal halide lamp, or the like, or by irradiation with electron beams in a wavelength region of 100 nm or less, emitted from a scanning- or curtain-type electron beam accelerator.

The thickness of a bleedout preventing layer is 1 to 10 μm and preferably 2 to 7 μm. By being to be 1 μm or more, it is easy that heat resistance as a film is to be sufficient, and by being to be 10 μm or less, it is easy to adjust the balance in the optical properties of the smooth film and also prevent the curl of the barrier film in the case of providing the smooth layer on one side of the transparent polymer film.

In addition to the above-described films, as the gas barrier film of the present invention, the films disclosed on Paragraphs [0036] to [0038] of Japanese Patent Application Laid-Open No. 2006-289627 may be preferably employed.

<Electronic Device>

The gas barrier film can be preferably applied to the device, in which the performance thereof is deteriorated by the chemical components in the air (oxygen, water, nitrogen oxide, sulfur oxide, ozone, and the like). Examples of the above devices may include an electronic device such as an organic EL element, a liquid crystal display device, a thin film transistor, a touch panel, an electronic paper, a solar cell, and the like, and the gas barrier film is preferably used for an organic EL element.

The gas barrier film may be also used for a film sealing of a device. In other words, this is a method in that the device itself is used as a support, and the gas barrier film of the present invention is provided on the surface thereof. Before providing the gas barrier film, the device may be covered with a protecting layer.

The gas barrier film of the present invention may be used as a substrate of a device or a film for sealing by a solid sealing method. The solid sealing method is a method comprising forming a protecting layer on a device, overlapping an adhesive layer and the gas barrier film, and curing them. An adhesive is not particularly limited, but examples thereof may include a thermosetting epoxy resin, a photosetting acrylate resin, and the like.

(Organic EL Element)

Examples of the organic EL element using the gas barrier film are disclosed in Japanese Patent Application Laid-Open No. 2007-30387.

(Liquid Crystal Display Element)

The reflection type liquid crystal display device is configured to include a lower substrate, a reflection electrode, a lower alignment film, a liquid crystal layer, an upper alignment film, a transparent electrode, an upper substrate, a λ/4 plate and a polarizing film in order from the lower side. The gas barrier film of the present invention can be used as the transparent electrode substrate and the upper substrate. In the case of giving a color displaying function to the reflection type liquid crystal display device, it is preferable to further provide a color filter layer between the reflection electrode and the lower alignment film or between the upper alignment film and the transparent electrode. Also, the transmission type liquid crystal display device is configured to include a backlight, a polarizing plate, a λ/4 plate, a lower transparent electrode, a lower alignment film, a liquid crystal layer, an upper alignment film, an upper transparent electrode, an upper substrate, a λ/4 plate and a polarizing film in order from the lower side. In the case of giving a color displaying function to the transmission type liquid crystal display device, it is preferable to further provide a color filter layer between the lower transparent electrode and the lower alignment film or between the upper alignment film and the upper transparent electrode. A kind of the liquid crystal cell is not particularly limited, but it is more preferably a TN (Twisted Nematic) type, an STN (Super Twisted Nematic) type, an HAN (Hybrid Aligned Nematic) type, a VA (Vertically Alignment) type, an ECB (Electrically Controlled Birefringence) type, an OCB (Optically Compensated Bend) type, an IPS (In-Plane Switching) type, or a CPA (Continuous Pinwheel Alignment) type.

(Solar Cell)

The gas barrier film of the present invention may be also used as a sealing film of a solar cell element. Here, the gas barrier film of the present invention preferably seals such that an adhesive layer is to be a close side to the solar cell element. The solar cell element that preferably uses the gas barrier film of the present invention is not particularly limited, but examples thereof may include a single crystal silicon-based solar cell element, a polycrystalline silicon-based solar cell element, an amorphous silicon-based solar cell element that is configured of a single mating type or a tandem structure type, a semiconductor solar cell element of III-V group compounds such as gallium arsenide (GaAs) or indium phosphorus (InP), a semiconductor solar cell element of II-VI group compounds such as cadmium tellurium (CdTe), a semiconductor solar cell element of I-III-VI group compounds such as copper/indium/selenium system (so-called CIS system), copper/indium/gallium/selenium system (so-called CIGS system), or copper/indium/gallium/selenium/sulfur system (so-called CIGSS system), a dye-sensitized solar cell element, an organic solar cell element, and the like. Among them, in the present invention, the solar cell element is preferably a semiconductor solar cell element of I-III-VI group compounds such as copper/indium/selenium system (so-called CIS system), copper/indium/gallium/selenium system (so-called CIGS system), or copper/indium/gallium/selenium/sulfur system (so-called CIGSS system).

(Others)

As other application examples, there are a thin film transistor disclosed in Japanese Patent Application National Publication (Laid-Open) No. 10-512104, a touch panel disclosed in Japanese Patent Application Laid-Open No. 5-127822 or Japanese Patent Application Laid-Open No. 2002-48913, an electronic paper disclosed in Japanese Patent Application Laid-Open No. 2000-98326, and the like.

(Optical Members)

The gas barrier film of the present invention may be used as an optical member. Examples of the optical members may include a circularly polarizing plate, and the like.

(Circularly Polarizing Plate)

The circularly polarizing plate can be prepared by laminating a λ/4 plate and a polarizing plate on the gas barrier film of the present invention as a substrate. In that case, the both plates are laminated in such a manner that a slow axis of the λ/4 plate and an absorption axis of the polarizing plate form an angle of 45°. As such a polarizing plate, one stretched in a direction of 45° against the machine direction (MD) thereof is preferably used, and those described in, for example, Japanese Patent Application Laid-Open No. 2002-865554 may be favorably used.

<Respective Characteristic Values of Gas Barrier Film>

The respective characteristic values of the gas barrier film of the present invention may be measured by using the following methods.

(Measurement of Water Vapor Permeability)

Various methods for measuring water vapor permeability according to a B method disclosed in JIS K 7129 (1992) have been proposed. Examples thereof may representatively include a cup method, a dryness and moisture sensor method (Lassy method), and an infrared sensor method (mocon method). However, as a gas barrier property is improved, there may be a measurement limit by these methods, and thus, the following methods have been proposed.

(Measuring Method of Water Vapor Permeability in Addition to the Above Method)

1. Ca Method

A metal Ca was vapor-deposited on the gas barrier film, and the corrosion phenomenon of the metal Ca is used with the water permeating through the film. The water vapor permeability is calculated with the corrosion area and the time for reaching there.

2. Method Suggested by MORESCO Co., Ltd. (Dec. 8, 2009, News Release)

A method for delivering through a cooling trap of water vapor between the sample space under the atmosphere pressure and the mass spectrometer in ultra-high vacuum.

3. HTO Method (US General Atomics Co., Ltd.)

A method for calculating water vapor permeability using tritium.

4. Method Suggested by A-Star (Singapore) (International Patent Publication No. 2005/95924)

A method for calculating water vapor permeability with electrical resistance changes and fluctuation components included therein for the materials (for example, Ca and Mg), in which the electrical resistance thereof is changed by water vapor or oxygen, using a sensor.

For the gas barrier film of the present invention, the method for measuring water vapor permeability is not particularly limited, but in the present specification, as the method for measuring water vapor permeability, the measurement is performed by the above-described Ca method, and then, the value obtained by performing the above method is defined to be water vapor permeability (g/m²·24 h).

The water vapor permeability of the gas barrier film of the present invention is preferably low, preferably 1×10⁻⁷ to 5×10⁻² g/m²·24 h, and more preferably, 1×10⁻⁶ to 1×10⁻² g/m²·24 h. In addition, for the gas barrier film of the present invention, the method for measuring water vapor permeability is not particularly limited, but the water vapor permeability is represented by a value measured by the above-described Ca method.

(Measurement of Oxygen Permeability)

The oxygen permeability was measured based on the B method (Isopiestic pressure method) disclosed in JIS K7126 (1987) using an oxygen permeability measuring apparatus (Apparatus name, “OXTRAN” (Registered trademark) (“OXTRAN” 2/20) manufactured by MOCON, Inc. USA. in the condition of a temperature of 23° C. and a humidity of 0% RH. In addition, the measurement to two test members was performed one time for each, and the average value of two measuring values was defined as the value of the oxygen permeability.

The oxygen permeability of the gas barrier film of the present invention is preferably low, but for example, preferably 0.01 g/m²·24 h·atm or less, more preferably 0.001 g/m²·24 h·atm or less, and still more preferably, less than 0.001 g/m²·24 h·atm (less than detection limit).

### EXAMPLES

The effect of the present invention will be described with reference to the following Examples and Comparative Examples. However, the technical range of the present invention is not limited to the following Examples.

The respective characteristic values of the gas barrier film were measured by using the following methods.

<<Evaluation of Gas Barrier Film>>

[Measurements of x and y in SiOxN_{y}] The gas barrier layer of each of the gas barrier films was measured by an XPS method. In detail, x and y in SiOxN_{y} were calculated by measuring Mg as X-rays anode and 600 W output (Acceleration voltage of 15 kV and emission electric current of 40 mA) using ESCALAB-200R manufactured by VG Scientific Co. Ltd.

(Evaluation of Water Vapor Barrier Property)

According to the following measuring method, the permeable water amounts of each of the gas barrier films were measured, and then, the water vapor barrier properties were evaluated according to the following standards.

(Apparatus)

Vapor deposition device: Vacuum vapor deposition device, JEE-400, manufactured by JEOL, Ltd.

Isothermal-isohumidity oven: Yamato Humidic Chamber IG47M

Metal that is corroded by reacting with water: Calcium

(Particle Materials)

Water vapor-nonpermeable metal: aluminum (φ3 to 5 mm, particle materials)

(Preparation of Cell for Evaluating Water Vapor Barrier Property)

On the side of the gas barrier layer of the sample, metal calcium was vapor-deposited by masking the parts other than the parts of the gas barrier film sample (nine parts of 12 mm×12 mm) to be desirably vapor-deposited before adhering a transparent conductive film using a vacuum vapor deposition device (a vacuum vapor deposition device, JEE-400, manufactured by JEOL Ltd). Then, the mask was removed in a vacuum state as it was to vapor-deposit aluminum from another metal deposition source on the whole surface of one side of the sheet. After the aluminum sealing, the vacuum state was removed, and then quickly, ultraviolet rays were irradiated on a quartz glass having a thickness of 0.2 mm through the ultraviolet rays curing resin for sealing (manufactured by Nagase ChemteX Corporation) to be faced to the aluminum sealing side under a dry nitrogen gas atmosphere to prepare a cell for being evaluated. In addition, in order to confirm the change of the gas barrier properties before and after bending, for the gas barrier film without being subjected to a bending treatment and the gas barrier film treated by the following bending treatment, similarly, the cells for evaluating the water vapor barrier property were prepared.

The samples, in which the obtained both sides were sealed, were stored under the high-temperature and high-humidity of 60° C. and 90% RH, and the amount of the water that was transmitted into a cell was calculated by using a corrosion amount of a metal calcium based on the method disclosed in Japanese Patent Application Laid-Open No. 2005-283561.

In addition, in order to confirm that there is not transmission of the water vapor from any sides other than the sides of the gas barrier films, as a comparison sample, the sample deposited with a metal calcium using a quartz glass plate having a thickness of 0.2 mm instead of the gas barrier film sample was stored in the same conditions of the high-temperature and high-humidity of 60° C. and 90% RH, and then, after passing 1000 hours, it was confirmed that there are no calcium corrosions.

The permeated water amount (g/m²·24 h; WVTR) of each of the gas barrier films measured as described above was evaluated.

(Evaluation of Bending Resistance)

For each of the gas barrier films, 100 times of bending at an angle of 180° were repeated so as to be the radius having a curvature of 10 mm, and then, the permeated water amount was measured in the same method as described above. Then, with the change of the permeated water amounts before and after the bending treatment, the deterioration resistance rate was measured by the following equation, and then, the bending resistance was evaluated according to the following criteria.

Deterioration resistance rate=(permeated water amount after bending test/permeated water amount before bending test)×100(%)

Rank of Bending Property

5: Deterioration resistance rate of 90% or more

4: Deterioration resistance rate of 80% or more and less than 90%

3: Deterioration resistance rate of 60% or more and less than 80%

2: Deterioration resistance rate of 30% or more and less than 60%

1: Deterioration resistance rate of less than 30%

[Measurement of Visible Transmittance: Transparency]

The average transmittance (%) of the visible light (400 to 720 nm) for each of the gas barrier films was measured by using a spectrophotometer V-570 (manufactured by JASCO Corporation).

### Examples 1 and 2 and Comparative Examples 1 to 3

### Example 1

### Preparation of Gas Barrier Film A-1

(Formation of Anchor Coat Layer)

A corona discharge treatment, an UV radiation treatment, and further a glow discharge treatment were performed on both sides of the substrate film (cutting polyethersulfone film (a PES film, a thickness of 188 μm, Product Name: SUMIKA Excel 4101GL30, manufactured by SUMITOMO CHEMICAL Co., Ltd) in a 20 cm square), and then, the lower coating solution of 0.1 g/m² of gelatin, 0.01 g/m² of α-sulfodi-2-ethylhexylsuccinic acid sodium, 0.04 g/m² of salicyclic acid, 0.2 g/m² of p-chlorophenol, 0.012 g/m² of (CH₂═CHSO₂CH₂CH₂NHCO)₂CH₂, and 0.02 g/m² of polyamide-epichlorohydrin polycondensate was applied on one side (using a bar coater of 10 mL/m²) to provide an anchor coat layer. The drying was performed at 115° C. for 6 minutes (all of the roller or transport system or in the drying zone were to be 115° C.).

(Formation of First Barrier Layer)

(Formation of Inorganic Barrier Layer by ALD Method)

A thin film of Al₂O₃ was deposited with an ALD reactor, F-120 model, manufactured by ASM Microchemistry Oy in Finland. Trimethyl aluminum (TMA) and water were used as an aluminum source and an oxygen source, respectively.

A substrate film applied with an anchor coat layer was installed in the reactor to be the anchor coat layer as the top surface, and then the reactor was vacuumed by pulling the reactor with a vacuum pump. Subsequently, a nitrogen gas was purged to adjust the pressure in the reactor to be about 600 to 800 Pa, and next, the temperature in the reactor was heated to be 230° C. Subsequently, the raw materials in a pulse phase were introduced in the reactor in the following cycle. The pulse cycles were TMA: 0.5 second, a nitrogen purge: 1.0 second, water: 0.4 second, and a nitrogen purge: 1.5 seconds. At this time, the deposition rate of Al₂O₃ in TMA and water was 0.07 nm/cycle. Here, the thin film of Al₂O₃ having a thickness of 70 nm was provided by performing 1000 cycles.

(Formation of Second Barrier Layer)

10 mass % of the dibutyl ether solution of perhydropolysilazane (AQUAMICA NN120-10, a noncatalytic type, manufactured by AZ Electronic Materials) was used as a polysilazane coating solution.

The polysilazane coating solution was applied on a first barrier layer so as to be a (average) film thickness of 300 nm after drying by a wireless bar, and then dried by treating under the atmosphere of a temperature of 85° C. and a humidity of 55% RH for 1 minute. Then, it was maintained under the atmosphere of a temperature of 25° C. and a humidity of 10% RH (a dew-point temperature of −8° C.) for 10 minutes, and then, was subjected to a dehumification treatment to form a coating film.

(Conversion Treatment of Coating Film into Silica by Ultraviolet Light)

Subsequently, the above coating film formed was subjected to a conversion treatment into silica under the condition of a dew-point temperature of −8° C. or lower by the following method to form a polysilazane layer (a second barrier layer).

<Ultraviolet Rays Irradiation Apparatus>

Apparatus: Excimer irradiation apparatus, MODEL: MECL-M-1-200, manufactured by M.D.COM, Inc.

Irradiation wavelength: 172 nm

Lamp filler gas: Xe

<Conversion Treatment Condition>

The conversion treatment was performed to the substrate having a polysilazane layer fixed on an operation stage under the following conditions to form a gas barrier layer.

Excimer Lamplight intensity: 130 mW/cm² (172 nm)

Distance between sample and light source: 1 mm

Stage heating temperature: 70° C.

Oxygen concentration in irradiation apparatus: 1.0%

Excimer lamp irradiation time: 5 seconds

(Formation of Third Barrier Layer)

Subsequently, a thin film of Al₂O₃ by the ALD method was formed on the polysilazane layer in the same condition as the formation of the first barrier layer to obtain the gas barrier film A-1 of Example 1, which has a three-layer lamination structure of an inorganic barrier layer (a first barrier layer)/a polysilazane layer (a second barrier layer)/an inorganic barrier layer (a third barrier layer).

### Example 2

### Formation of Gas Barrier Film A-2

A polysilazane layer and a third barrier layer were further formed on the gas barrier film A-1 in the same method as the formation method of the gas barrier film A-1 to obtain the gas barrier film A-2 of Example 2, which has the constitution of an inorganic barrier layer (the first barrier layer of the first gas barrier unit)/a polysilazane layer (the second barrier layer of the first gas barrier unit)/an inorganic barrier layer (the third barrier layer of the first gas barrier unit and the first barrier layer of the second gas barrier unit)/a polysilazane layer (the second barrier layer of the second gas barrier unit)/an inorganic barrier layer (the third barrier layer of the second gas barrier unit).

### Comparative Example 1

### Formation of Gas Barrier Film A-11

A gas barrier film A-11 of Comparative Example 1 was formed in the same method as the gas barrier film A-1, except that instead of the formation of the polysilazane layer, a silicon oxide film (a film thickness of 300 nm) formed by a general plasma CVD (PECVD) was formed on the first barrier layer.

### Comparative Example 2

### Formation of Gas Barrier Film A-12

A gas barrier film A-12 of Comparative Example 2 was formed in the same method as the gas barrier film A-1, except that instead of the layer formed with polysilazane, an organic layer was formed on the first barrier layer in the following method.

An acrylic monomer mixture of 50.75 mL of tetraethyleneglycol diacrylate, 14.5 mL of tripropylene glycolmonoacrylate, 7.25 mL of caprolactone acrylate, 10.15 mL of acrylic acid, and 10.15 mL of SarCure (benzophenone mixture photopolymerizable initiator manufactured by Sartomer) was mixed with 36.25 gm of solid N,N′-bis(3-methylphenyl)-N,N′-diphenylbenzidine particles and then the mixture thus obtained was stirred for about 1 hour with a 20 kHz ultrasonic wave tissue blender. The mixture was heated at about 45° C., and the stirred mixture in order to prevent the sedimentation was transferred by a pump into a 1.3 mm spray nozzle through a capillary having an inside diameter of 2.0 mm and a length of 61 mm, and then, sprayed in a small drop through a 25 kHz ultrasonic waves sprayer, and thus dropped on the surface maintaining about 340° C. The steam was cryo-condensed on the plastic substrate that was the same as Example 1 that came in contact with a low temperature drum having a temperature of about 13° C., and then, cured with UV by a high pressure mercury vapor lamp (the estimated irradiation amount of about 2000 mJ/cm²) to form an organic layer. The film thickness thereof was about 300 nm.

### Comparative Example 3

### Formation of Gas Barrier Film A-13

A gas barrier film A-13 of Comparative Example 3 was formed in the same method as the gas barrier film A-1, except that the third barrier layer was not formed.

For the gas barrier films A-1 and A-2, and the gas barrier films A-11 and A-12 for comparisons, the layer configurations other than the substrates are listed in the following Table 1.

TABLE 1

| No. | Layer configuration (layer film thickness in parenthesis) |
|---|---|
| A-1 | Al₂O₃ film (70 nm)/polysilazane layer (300 nm)/Al₂O₃ |
| | film (70 nm) |
| A-2 | Al₂O₃ film (70 nm)/polysilazane layer (300 nm)/Al₂O₃ |
| | film (70 nm)/polysilazane layer (300 nm)/Al₂O₃ film (70 nm) |
| A-11 | Al₂O₃ film (70 nm)/silicon oxide film (300 nm)/Al₂O₃ |
| | film (70 nm) |
| A-12 | Al₂O₃ film (70 nm)/organic layer (300 nm)/Al₂O₃ film (70 nm) |
| A-13 | Al₂O₃ film (70 nm)/polysilazane layer (300 nm) |

(Test and Evaluation)

For the gas barrier films A-1 and A-2, and the gas barrier films A-11 and A-12 for comparisons, the gas barrier properties were evaluated. The results are listed in Table 2.

TABLE 2

| | Conversion condition of | | | | | |
|---|---|---|---|---|---|---|
| | polysilazane coating film | | | | | |
| | Heating | Irradiation | | Rank of | | |
| | temperature | time | WVTR | Bending | Transparency | |
| No. | (° C.) | (seconds) | g/m² · 24 h | property | (%) | |
| A-1 | 70 | 5 | 0.001 | 4 | 93 | Example |
| A-2 | 70 | 5 | 0.0005 | 5 | 92 | Example |
| A-11 | — | — | 0.02 | 2 | 82 | Comparative |
| | | | | | | Example |
| A-12 | — | — | 0.03 | 2 | 81 | Comparative |
| | | | | | | Example |
| A-13 | 70 | 5 | 0.05 | 1 | 92 | Comparative |
| | | | | | | Example |

From the results listed in Table 2, it can be confirmed that as compared with the gas barrier films A-11, A-12, and A-13 for comparisons, the gas barrier films A-1 and A-2 have favorable gas barrier properties (WVTR), bending resistances (bending properties), and high visible light transmittance.

### Examples 3 and 4 and Comparative Examples 4 to 6

A gas barrier film B-1 of Example 3, a gas barrier film B-2 of Example 4, a gas barrier film B-11 of Comparative Example 4, a gas barrier film B-12 of Comparative Example 5, and a gas barrier film B-13 of Comparative Example 6 were formed in the same methods as Example 1, Example 2, Comparative Example 1, Comparative Example 2, and Comparative Example 3, respectively, except that the plastic base materials and inorganic layers were formed in the following methods.

In addition, for the following Examples and Comparative Examples, the same number next to alphabet-exhibits the gas barrier films that are prepared in the same conditions thereof except the specific conditions described.

The barrier layers were formed on the smoothing surface sides of a polyethylene naphthalate film (a PEN film, a thickness of 100 μm, Product Name: Teonex Q65FA manufactured by Teijin DuPont Films Japan Limited) along the following method, and then were evaluated.

The splice roll was loaded in a roll-to-roll sputter coater. The pressure in the film formation chamber was reduced by a pump to be 2×10⁻⁶ Torr. The gas mixture including 51 sccm of argon and 30 scorn of oxygen in 2 kW, 600 V, and 1 millitorr pressure and a Si—Al (95/5) target (available from Academy Precision Materials as a product on the market) using a web rate of 0.43 m/min were reactive-sputtered to deposit a SiAlO inorganic oxide layer (a first barrier layer) having a thickness of 60 nm on a substrate film. Similarly, the third barrier layer was formed on the second barrier layer.

For the gas barrier films B-1 and B-2, and the gas barrier films B-11 and B-12 for comparisons, the layer configurations other than the substrates are listed in the following Table 3. In addition, the results of evaluating the gas barrier properties are listed in Table 4.

TABLE 3

| No. | Layer configuration (layer film thickness in parenthesis) |
|---|---|
| B-1 | SiAlO film (60 nm)/polysilazane layer (300 nm)/SiAlO |
| | film (60 nm) |
| B-2 | SiAlO film (60 nm)/polysilazane layer (300 nm)/SiAlO film |
| | (60 nm)/polysilazane layer (300 nm)/SiAlO film (60 nm) |
| B-11 | SiAlO film (60 nm)/silicon oxide film (300 nm)/SiAlO |
| | film (60 nm) |
| B-12 | SiAlO film (60 nm)/organic layer (300 nm)/SiAlO |
| | film (60 nm) |
| B-13 | SiAlO film (60 nm)/polysilazane layer (300 nm) |

TABLE 4

| | Conversion condition of | | | | | |
|---|---|---|---|---|---|---|
| | polysilazane coating film | | | | | |
| | Heating | Irradiation | | Rank of | | |
| No. | temperature | time | WVTR | Bending | Transparency | |
| No. | (° C.) | (seconds) | g/m₂ · 24 h | property | (%) | |
| B-1 | 70 | 5 | 0.002 | 4 | 91 | Example |
| B-2 | 70 | 5 | 0.008 | 5 | 90 | Example |
| B-11 | — | — | 0.01 | 2 | 80 | Comparative |
| | | | | | | Example |
| B-12 | — | — | 0.02 | 2 | 81 | Comparative |
| | | | | | | Example |
| B-13 | 70 | 5 | 0.06 | 2 | 95 | Comparative |
| | | | | | | Example |

From the results listed in Table 4, it can be confirmed that as compared with the gas barrier films B-11, B-12, and B-13 for comparisons, the gas barrier films B-1 and B-2 have favorable gas barrier properties (WVTR), bending resistances (bending properties), and high visible light transmittance.

### Examples 5 and 6 and Comparative Examples 7 to 9

A gas barrier film C-1 of Example 5, a gas barrier film C-2 of Example 6, a gas barrier film C-11 of Comparative Example 6, a gas barrier film C-12 of Comparative Example 7, and a gas barrier film C-13 of Comparative Example 8 were respectively formed in the same methods as Example 1, Example 2, Comparative Example 1, Comparative Example 2, and Comparative Example 3, respectively, except that the plastic base materials and inorganic layers were formed in the following methods.

A polyethylene naphthalate film (a PEN film, a thickness of 100 μm, Product Name: Teonex Q65FA manufactured by Teijin DuPont Films Japan Limited) was cut in a 20 cm square, and then the barrier layers in the following orders were formed on the smoothing surface sides thereof.

The reactive sputtering was performed using a sputter apparatus under the following conditions to deposit a SiNH layer having a thickness of 50 nm on the substrate film. Similarly, the third barrier layer was formed on the second barrier layer.

Film Formation Condition:

Plasma generation gas: Argon, nitrogen

Gas flow rate: Argon 100 sccm, Nitrogen 60 sccm

Target material: Si

Electricity level: 2.5 kW

Vacuum chamber internal pressure: 0.15 Pa (0.75 millitorr)

For the gas barrier films C-1 and C-2, and the gas barrier films C-11, C-12, and C-13 for comparisons, the layer configurations other than the substrates are listed in the following Table 5. In addition, the results of evaluating the gas barrier properties are listed in Table 6.

TABLE 5

| No. | Layer configuration (layer film thickness in parenthesis) |
|---|---|
| C-1 | SiNH film (50 nm)/polysilazane layer (300 nm)/SiNH film (50 nm) |
| C-2 | SiNH film (50 nm)/polysilazane layer (300 nm)/SiNH |
| | film (50 nm)/polysilazane layer (300 nm)/SiNH film (50 nm) |
| C-11 | SiNH film (50 nm)/silicon oxide film (300 nm)/SiNH film (50 nm) |
| C-12 | SiNH film (50 nm)/organic layer (300 nm)/SiNH film (50 nm) |
| C-13 | SiNH film (50 nm)/polysilazane layer (300 nm) |

TABLE 6

| | Conversion condition of | | | | | |
|---|---|---|---|---|---|---|
| | polysilazane coating film | | | | | |
| | Heating | Irradiation | | Rank of | | |
| No. | temperature | time | WVTR | Bending | Transparency | |
| No. | (° C.) | (seconds) | g/m² · 24 h | property | (%) | |
| C-1 | 70 | 5 | 0.003 | 5 | 92 | Example |
| C-2 | 70 | 5 | 0.007 | 5 | 91 | Example |
| C-11 | — | — | 0.01 | 2 | 79 | Comparative |
| | | | | | | Example |
| C-12 | — | — | 0.02 | 2 | 81 | Comparative |
| | | | | | | Example |
| C-13 | 70 | 5 | 0.06 | 2 | 95 | Comparative |
| | | | | | | Example |

From the results listed in Table 6, it can be confirmed that as compared with the gas barrier films C-11, C-12, and C-13 for comparisons, the gas barrier films C-1 and C-2 have favorable gas barrier properties (WVTR), bending resistances (bending properties), and high visible light transmittance.

### Examples 7 to 16 and Comparative Examples 10 to 12

The gas barrier films D-1 to N-1 of Examples 7 to 16 were formed in the same methods as Example 1, except that the plastic base materials and inorganic layers were formed in the following methods.

In addition, a gas barrier film D-11 of Comparative Example 7, a gas barrier film D-12 of Comparative Example 8, and a gas barrier film D-13 of Comparative Example 9 were formed in the same methods as Comparative Example 1, Comparative Example 2, and Comparative Example 3, respectively, except that the plastic base materials and inorganic layers were formed in the following methods.

[Formation of Oxynitride Film]

Using a general CVD apparatus (PD-220NA manufactured by SAMCO Inc.) that performs a film formation by a capacity-binding plasma CVD method, as a first barrier layer, a silicon oxynitride film having a film thickness of 100 nm was formed on a plastic substrate. As a third barrier layer, similarly, a silicon oxynitride film having a thickness of 100 nm was formed on a polysilazane layer.

As a plastic substrate, a polyethylene naphthalate film (a PEN film, a thickness of 100 μm, Product Name: Teonex Q65FA manufactured by Teijin DuPont Films Japan Limited) was used. In addition, the area of the substrate was to be 300 cm².

The substrate is set at a predetermined location in the vacuum chamber, and then a vacuum chamber was closed. Subsequently, the inside of the vacuum chamber was exhausted, and then, at the point for the pressure to be 0.01 Pa, a silane gas (5% nitrogen dilution), an oxygen gas (5% nitrogen dilution), and a nitrogen gas were introduced as a reactive gas. In addition, the flow rates of a silane gas, an oxygen gas, and a nitrogen gas were set to be the same as disclosed in Table 7 for the respective gas barrier films. In addition, the exhaust of inside of the vacuum chamber was adjusted such that the pressure in the vacuum chamber was to be the same as disclosed in Table 7 for the respective barrier films. In addition, in order to change the composition ratios for the gas barrier films D-1 to N-1, the reactive gas flow rates were adjusted as listed in Table 7.

TABLE 7

| | | Flow rate | Flow rate | Flow rate | Film |
|---|---|---|---|---|---|
| | | of silane | of oxygen | of N₂ | formation |
| | | gas | gas | gas | pressure |
| | No. | [sccm] | [sccm] | [sccm] | [Pa] |
| Example | D-1 | 50 | 2.5 | 150 | 100 |
| | E-1 | 50 | 2.5 | 150 | 166 |
| | F-1 | 50 | 1.25 | 150 | 100 |
| | G-1 | 50 | 0.5 | 150 | 100 |
| | H-1 | 50 | 5 | 150 | 100 |
| | I-1 | 50 | 6.25 | 150 | 100 |
| | J-1 | 50 | 5 | 150 | 133 |
| | K-1 | 50 | 1.25 | 150 | 66.6 |
| | L-1 | 50 | 2.5 | 150 | 50 |
| | N-1 | 50 | 5 | 150 | 166 |
| Comparative | D-11 | 50 | 2.5 | 150 | 100 |
| Example | D-12 | 50 | 2.5 | 150 | 100 |
| | D-13 | 50 | 2.5 | 150 | 100 |

For the gas barrier films D-1 to N-1, and the gas barrier films D-11, D-12, and D-13 for comparisons, the layer configurations other than the substrates are listed in the following Table 8. In addition, the results of evaluating the gas barrier properties are listed in Table 9.

TABLE 8

| No. | Layer configuration (layer film thickness in parenthesis) |
|---|---|
| D-1 to | SiOₓN_{y} film (100 nm)/polysilazane layer (300 nm)/SiOₓN_{y} |
| N-1 | film (100 nm) |
| D-11 | SiOₓN_{y} film (100 nm)/silicon oxide film (300 nm)/SiOₓN_{y} |
| | film (100 nm) |
| D-12 | SiOₓN_{y} film (100 nm)/organic layer (300 nm)/SiOₓN_{y} |
| | film (100 nm) |
| D-13 | SiOₓN_{y} film (100 nm)/polysilazane layer (300 nm) |

TABLE 9

| | Conversion condition of | | | | | | | |
|---|---|---|---|---|---|---|---|---|
| | polysilazane coating film | | | | | | | |
| | Heating | Irradiation | Composition ratio | | | | | |
| | temperature | time | of oxynitride film | | WVTR | Rank of Bending | Transparency | |
| No. | (° C.) | (seconds) | Si:O:N | O/N | g/m² · 24 h | property | (%) | |
| D-1 | 70 | 5 | 1:0.82:0.79 | 1 | 0.003 | 5 | 95 | Example |
| E-1 | 70 | 5 | 1:0.82:0.80 | 1 | 0.005 | 4 | 90 | |
| F-1 | 70 | 5 | 1:0.33:1.11 | 0.3 | 0.006 | 4 | 89 | |
| G-1 | 70 | 5 | 1:0.18:1.2 | 0.15 | 0.007 | 3 | 86 | |
| H-1 | 70 | 5 | 1:1.49:0.33 | 4.5 | 0.004 | 4 | 90 | |
| I-1 | 70 | 5 | 1:1.54:0.28 | 5.5 | 0.007 | 3 | 88 | |
| J-1 | 70 | 5 | 1:1.52:0.31 | 4.9 | 0.007 | 3 | 88 | |
| K-1 | 70 | 5 | 1:0.30:1.14 | 0.26 | 0.007 | 3 | 87 | |
| L-1 | 70 | 5 | 1:0.77:0.66 | 1.1 | 0.002 | 5 | 94 | |
| N-1 | 70 | 5 | 1:1.44:0.33 | 4.4 | 0.002 | 5 | 95 | |
| D11 | — | — | 1:0.82:0.79 | 1 | 0.01 | 2 | 79 | Comparative |
| | | | | | | | | Example |
| D12 | — | — | 1:0.82:0.79 | 1 | 0.01 | 2 | 81 | Comparative |
| | | | | | | | | Example |
| D13 | 70 | 5 | 1:0.82:0.79 | 1 | 0.008 | 2 | 96 | Comparative |
| | | | | | | | | Example |

From the results listed in Table 9, it can be confirmed that as compared with the gas barrier films D-11, D-12, and D-13 for comparisons, the gas barrier films D-1 to N-1 have favorable gas barrier properties (WVTR), bending resistances (bending properties), and high visible light transmittance.

<<Evaluation of Organic EL Element>>

### Examples 17 to 26 and Comparative Examples 13 to 15

Formation of organic EL element

(1) Preparation of Organic EL Element Substrate

A conductive glass substrate having an ITO film (surface resistivity value: 10Ω/□, a thickness of 0.6 mm) as an organic EL substrate was rinsed with 2-propanol and then subjected to a UV-ozone treatment for 10 minutes. The following organic compound layers were successively vapor-deposited on this substrate (anode) by a vacuum vapor deposition method.

(First Hole Transport Layer)

Copper phthalocyanine: a film thickness of 10 nm

(Second Hole Transport Layer)

N,N′-diphenyl-N,N′-dinaphthylbenzidine: a film thickness of 40 nm

(Light-Emitting Layer/Electron Transport Layer)

Iris (8-hydroxyquinolinato) aluminum: a film thickness of 60 nm

Finally, lithium fluoride having a film thickness of 1 nm and metal aluminum having a film thickness of 100 nm were successively vapor-deposited to form a cathode, and then a silicon nitride film having a film thickness of 5 μm was applied thereon by a plane-parallel plate CVD method, thereby preparing an organic EL element.

(2) Installment of Gas Barrier Film

The organic EL elements were sealed using each of the gas barrier films D-1 to N-1 prepared in Examples 7 to 16 and the gas barrier films D-11, D-12, and D-13 prepared in Comparative Examples 10 to 12 as a sealing film. In detail, the gas barrier film was overlapped on the element side of the organic EL element using a thermosetting resin such that the barrier surface side came in contact with the organic EL element side, and the organic EL element was sealed by laminating with a vacuum laminator installed in a nitrogen purge glove box, and then heating the organic EL element at 100° C. for 1 hour.

(3) Method of Evaluating Organic EL Element

The durability of the organic EL element prepared as described above was evaluated by the following method.

(Accelerated Deterioration Treatment)

The element produced as described above was left for 750 hours under the environment of 60° C. and 90% RH, followed by carrying out a counting of the number of the dark spot (a non-light-emitting part) as described below, together with organic EL elements that had not been subjected to the accelerated deterioration treatment. In other words, an electric current of 1 mA/cm² was applied to each of the organic El elements that had been subjected to the accelerated deterioration treatment (“after 750 hours” in Table 10) and the organic EL elements that had not been subjected to the accelerated deterioration treatment (“initial stage” in Table 10) and light was continuously emitted for 24 hours, followed by magnifying a part of a panel by a 100-time microscope (MS-804 manufactured by Moritex Corporation, lens MP-ZE25-200) to be photographed. A captured image was cut into a 2 mm square part, and then the number of dark spots (a non-light-emitting part) was counted. The results thereof are listed in Table 10. In addition, in Table 10, when the number of dark spots is not changed, it is determined as “OK” and when it is increased, it is determined as “NG.”

TABLE 10

| | Number of | Number of | |
|---|---|---|---|
| | dark spots | dark spots | |
| No. | Initial stage | After 750 hours | Decision |
| D-1 | 0 | 0 | OK |
| E-1 | 1 | 1 | OK |
| F-1 | 1 | 1 | OK |
| G-1 | 1 | 1 | OK |
| H-1 | 1 | 1 | OK |
| I-1 | 1 | 1 | OK |
| J-1 | 1 | 1 | OK |
| K-1 | 1 | 1 | OK |
| L-1 | 1 | 1 | OK |
| N-1 | 1 | 1 | OK |
| D-11 | 5 | 19 | NG |
| D-12 | 5 | 22 | NG |
| D-13 | 5 | 20 | NG |

As clearly listed in the above Table 10, it can be confirmed that for the organic EL elements having the gas barrier films D-1 to N-1 according to the present invention, the change of the number of the dark spots is few and excellent durability is exhibited, as compared with the organic EL elements having the gas barrier films D-11 and D-12 in Comparative Examples.

The present application is based on Japanese Patent Application No. 2012-101644 filed on Apr. 26, 2012, and its disclosure is incorporated herein by reference in its entirety.

1. A gas barrier film comprising:
a substrate, and
a gas barrier unit being arranged on at least one side of the substrate,
wherein the gas barrier unit comprises a first barrier layer including an inorganic substance, a second barrier layer obtained by performing a conversion treatment to a coating film formed by coating polysilazane onto the first barrier layer, and a third barrier layer including an inorganic substance in order.

2. The gas barrier film according to claim 1, wherein the conversion treatment is a treatment of irradiating vacuum ultraviolet rays.

3. The gas barrier film according to claim 1, wherein the gas barrier units are repeatedly arranged.

4. The gas barrier film according to claim 1, wherein the inorganic substance is at least one kind of oxide, nitride, or oxynitride of at least one kind of Si and Al.

5. The gas barrier film according to claim 1, wherein the first and third barrier layers are formed by any one method of a chemical vapor deposition method, a physical vapor deposition method, and an atomic layer deposition method.

6. The gas barrier film according to claim 5, wherein the first and third barrier layers are formed by an atomic layer deposition method.

7. An electronic device using the gas barrier film according to claim 1.
